(19) United States
(12) Patent Application Publication
(10) Pub. No.: US 2026/0031124 A1
(43) Pub. Date: Jan. 29, 2026

(54) METHODS OF OPERATING NONVOLATILE MEMORY DEVICES HAVING FERROELECTRIC MEMORY CELLS THEREIN

(71) Applicant: Samsung Electronics Co., Ltd., Suwon-si (KR)

(72) Inventors: Haewook Jeong, Suwon-si (KR); Keonhee Park, Suwon-si (KR); Sunggyeong Lee, Suwon-si (KR)

(21) Appl. No.: 19/088,164

(22) Filed: Mar. 24, 2025

(30) Foreign Application Priority Data
Jul. 24, 2024 (KR) 10-2024-0098202

(51) Int. Cl. G11C 11/22

(52) U.S. Cl. CPC G11C 11/2275; G11C 11/221; G11C 11/2255

(57) ABSTRACT

A method of operating a ferroelectric memory cell includes performing a write operation on the ferroelectric memory cell based on a predetermined target state not corresponding to a saturation polarization state of a ferroelectric capacitor within the ferroelectric memory cell. The write operation includes applying a first removing voltage corresponding to the target state as an across voltage of the ferroelectric capacitor, then applying a first target voltage corresponding to the target state as the across voltage of the ferroelectric capacitor, and then applying 0 V, which differs from the first removing voltage and the first target voltage, as the across voltage of the ferroelectric capacitor.

### REFERENCE TO PRIORITY APPLICATION

This application claims priority under 35 U.S.C. § 119 to Korean Patent Application No. 10-2024-0098202, filed Jul. 24, 2024, the disclosure of which is hereby incorporated herein by reference in its entirety.

### BACKGROUND

Embodiments of the present disclosure described herein relate to memory devices and, more particularly, to methods of operating nonvolatile memory devices.

A semiconductor memory device is typically classified as either a volatile memory device, which loses data stored therein when power is turned off, such as a static random access memory (SRAM) or a dynamic random access memory (DRAM), or a nonvolatile memory device, which retains data stored therein even when power is turned off, such as a flash memory, a phase-change RAM (PRAM), a magnetic RAM (MRAM), a resistive RAM (RRAM), or a ferroelectric RAM (FRAM).

A ferroelectric memory is a type of nonvolatile memory, which can in some embodiments be similar in structure to the DRAM, but advantageously maintains data by using a ferroelectric capacitor that typically doesn't require periodic refresh and maintains data even when power is withdrawn. For example, a ferroelectric RAM can include a plurality of memory cells, and each of the plurality of memory cells can include a ferroelectric capacitor. As will be understood by those skilled in the art, a polarization state of the ferroelectric capacitor may typically be controlled by adjusting a voltage across the ferroelectric capacitor. In addition, data (e.g., 1-bit, 2-bit, etc.) stored in a memory cell may be determined as a function of the polarization state of the ferroelectric capacitor, and the polarization state of the ferroelectric capacitor may be maintained even when power is turned off.

### SUMMARY

Embodiments of the present disclosure provide methods of operating ferroelectric memory devices with reduced costs and improved performance.

According to an embodiment, a method of operating a memory device containing ferroelectric memory cells includes determining a target state among at least three states based on data to be written into the ferroelectric memory cell, and performing a write operation on the ferroelectric memory cell based on the target state. When the target state is a state that differs from a saturation polarization state of a ferroelectric capacitor included in the ferroelectric memory cell, then the write operation can include applying a first removing voltage corresponding to the target state as an across voltage of the ferroelectric capacitor, then applying a first target voltage corresponding to the target state as the across voltage of the ferroelectric capacitor, and then applying 0 V as the across voltage of the ferroelectric capacitor (while an access transistor of the ferroelectric memory cell remains turned on).

According to another embodiment, a method of operating a memory device containing ferroelectric memory cells includes determining a target state among at least three states based on data to be written into the ferroelectric memory cell, applying a first target voltage as an across voltage of a ferroelectric capacitor of the ferroelectric memory cell when the target state is a first target state, applying a second target voltage as the across voltage of the ferroelectric capacitor when the target state is a second target state, continuously applying a first removing voltage and a third target voltage as the across voltage of the ferroelectric capacitor when the target state is a third target state, continuously applying a second removing voltage and a fourth target voltage as the across voltage of the ferroelectric capacitor when the target state is a fourth target state, and applying 0 V as the across voltage of the ferroelectric capacitor.

According to a further embodiment, a method of operating a memory device containing a ferroelectric of memory cell includes performing a polarization removing operation on the ferroelectric memory cell, performing a target state setting operation on the ferroelectric memory cell, and performing a stabilization operation on the ferroelectric memory cell, in the event the ferroelectric memory cell has one of at least three states.

According to a still further embodiment, a method of operating a ferroelectric memory cell includes performing a write operation on the ferroelectric memory cell based on a predetermined target state, which is unequal to a saturation polarization state of a ferroelectric capacitor within the ferroelectric memory cell, by: (i) applying a first removing voltage corresponding to the target state as an across voltage of the ferroelectric capacitor; then (ii) applying a different first target voltage corresponding to the target state as the across voltage of the ferroelectric capacitor; and then (iii) applying 0 V, which differs from the first removing voltage and the first target voltage, as the across voltage of the ferroelectric capacitor.

According to further embodiments, a ferroelectric memory cell may include: (i) an access transistor having a gate terminal electrically coupled to a word line and a first source/drain terminal electrically connected to a bit line, and (ii) a ferroelectric capacitor having a first terminal electrically connected to a second source/drain terminal of the access transistor, and a second terminal electrically connected to a plate line. And, in these embodiments, a method of operating the ferroelectric memory cell may include performing a write operation on the ferroelectric memory cell to achieve a predetermined target state, which is unequal to a saturation polarization state of the ferroelectric capacitor within the ferroelectric memory cell, by turning on the access transistor via the word line, and then, while the access transistor remains on, (i) applying a first removing voltage across the first and second terminals of the ferroelectric capacitor, then (ii) applying a first target voltage unequal to the first removing voltage across the first and second terminals of the ferroelectric capacitor, and then (iii) applying 0 V, which differs from the first removing voltage and the first target voltage, across the first and second terminals of the ferroelectric capacitor.

According to additional aspects of these embodiments, the operation of applying a first removing voltage may be immediately preceded by applying 0 V across the first and second terminals of the ferroelectric capacitor before the access transistor is turned on. In addition, the first removing voltage may have an opposite polarity relative to the first target voltage, the first removing voltage is applied during a first time interval, the first target voltage is applied during a second time interval that commences upon termination of the first time interval, and the 0 V is applied during a third time interval that commences upon termination of the second time interval. Moreover, the operation of applying a first removing voltage may be performed concurrently with applying a non-zero bias having a first polarity to the plate line, and the operation of applying a first target voltage may be performed concurrently with applying a non-zero bias having the first polarity to the bit line. Finally, the operation of applying a first removing voltage may be performed concurrently with applying a 0 V bias to the bit line, and the operation of applying a first target voltage may be performed concurrently with applying a 0 V bias to the plate line.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a memory device according to an embodiment of the present disclosure.

FIG. 2 is a diagram illustrating a memory cell included in a memory cell array of FIG. 1.

FIGS. 3A to 3C are diagrams for describing a 2-level write operation on a memory cell.

FIGS. 4A to 4C are diagrams for describing a 2-level read operation on a memory cell of FIG. 2.

FIGS. 5 and 6 are diagrams for describing a multi-level operation of a memory device of FIG. 1.

FIG. 7 is a flowchart illustrating an operation of a memory device configured to perform a 4-level write operation described with reference to FIG. 5.

FIGS. 8 to 11D are diagrams for describing an operation according to the flowchart of FIG. 7.

FIG. 12 is a graph illustrating a simulation result of a memory cell according to the timing diagram of FIG. 10A.

FIG. 13 is a timing diagram for describing an operation of writing a third state in a memory cell, according to an embodiment of FIG. 5.

FIGS. 14A to 14C are diagrams for describing a read operation and a rewrite operation on a memory cell experiencing a 4-level write operation according an embodiment of FIG. 5

FIGS. 15A and 15B are diagrams for describing a multi-level operation of a memory device of FIG. 1.

FIGS. 16A and 16B are diagrams for describing a multi-level operation of a memory device of FIG. 1.

FIG. 17 is a block diagram illustrating a system according to an embodiment of the present disclosure.

FIG. 18 is a diagram of a system to which a storage device is applied, according to an embodiment.

### DETAILED DESCRIPTION

Below, embodiments of the present disclosure will be described in detail and clearly to such an extent that one of ordinary skill in the art may readily reproduce and carry out embodiments of the inventive concepts disclosed herein.

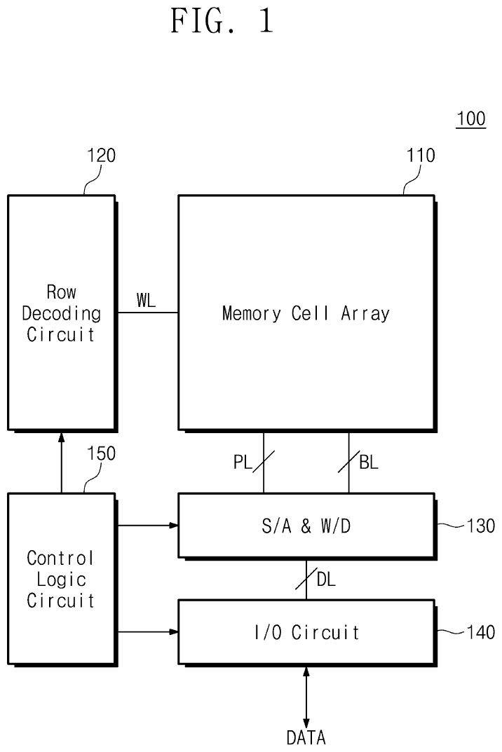

FIG. 1 is a block diagram illustrating a memory device 100 according to an embodiment of the present disclosure, which is illustrated as including a memory cell array 110, a row decoding circuit 120, a sense amplifier and write driver 130, an input/output circuit 140, and a control logic circuit 150. Under control of an external device (e.g., a controller), the memory device 100 may store data or may output the stored data.

The memory cell array 110 may include a plurality of memory cells arranged in rows and columns. The plurality of memory cells may be connected to word lines WL, plate lines PL, and bit lines BL. For example, memory cells located at the same row from among the plurality of memory cells may be connected to the same word line. Memory cells located at the same column from among the plurality of memory cells may be connected to the same plate line and the same bit line. However, the above arrangement of the memory cells is provided as an example, and the present disclosure is not limited thereto.

The row decoding circuit 120 may be connected to the memory cell array 110 through the word lines WL. The row decoding circuit 120 may control voltages of the word lines WL under control of the control logic circuit 150. In an embodiment, the row decoding circuit 120 may decode a row address received from the external device (e.g., a controller) and may control voltages of the word lines WL based on a decoding result.

The sense amplifier and write driver 130 may be connected to the memory cell array 110 through the plate lines PL and the bit lines BL. The sense amplifier and write driver 130 may receive data “DATA” from the input/output circuit 140 through data lines DL and may control voltages of the plate lines PL and the bit lines BL based on the received data “DATA”. The sense amplifier and write driver 130 may sense voltage changes of the bit lines BL and may read data stored in the memory cell array 110 based on the sensed voltage changes.

The input/output circuit 140 may exchange the data “DATA” with the external device (e.g., a controller). The input/output circuit 140 may transfer the data “DATA” to the sense amplifier and write driver 130 through the data lines DL or may receive the read data “DATA” from the sense amplifier and write driver 130 through the data lines DL

The control logic circuit 150 may control all the operations of the memory device 100. For example, the control logic circuit 150 may control the row decoding circuit 120, the sense amplifier and write driver 130, and the input/output circuit 140 such that the memory device 100 performs read and write operations.

In an embodiment, each of the plurality of memory cells included in the memory cell array 110 may be a “nonvolatile” ferroelectric memory cell. For example, the ferroelectric memory cell may include a ferroelectric capacitor. A polarization state or a polarization value of the ferroelectric capacitor may vary depending on a voltage across the ferroelectric capacitor. Advantageously, even though the voltage across the ferroelectric capacitor may be blocked, the ferroelectric capacitor has the characteristic that the polarization state or the polarization value is maintained. That is, the ferroelectric memory cell has a characteristic of being a nonvolatile memory, so that information or data corresponding to the polarization state or the polarization value of the ferroelectric capacitor is capable of being maintained during a given time. According to an embodiment of the present disclosure, each memory cell included in the memory cell array 110 may be configured to store multi-level information. For example, the polarization state or the polarization value of each memory cell included in the memory cell array 110 may be classified as a 3-state, a 4-state, a 5-state, etc., or may be set to a 3-state, a 4-state, a 5-state, etc. In this case, the amount of information or data to be stored in each memory cell may increase. The operation of the memory device 100 according to an embodiment of the present disclosure will be described in detail with reference to the following drawings.

The memory device 100 described with reference to FIG. 1 is provided as an example to describe an embodiment of the present disclosure easily, and the present disclosure is not limited thereto. The memory device 100 may further include a command buffer, an address buffer, etc. depending on a way to implement the memory device 100. In an embodiment, the memory device 100 may be similar in architecture to the DRAM device and may communicate with the external device based on an interface (e.g., a DDR interface or an LPDDR interface) of the DRAM device.

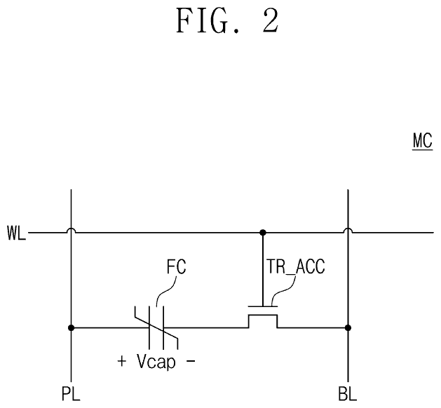

FIG. 2 is a diagram illustrating a memory cell, which may be utilized in the memory cell array 110 of FIG. 1; however, the present disclosure is not limited thereto. For example, each of the plurality of memory cells included in the memory cell array 110 may be similar or dissimilar in structure to the memory cell MC of FIG. 2.

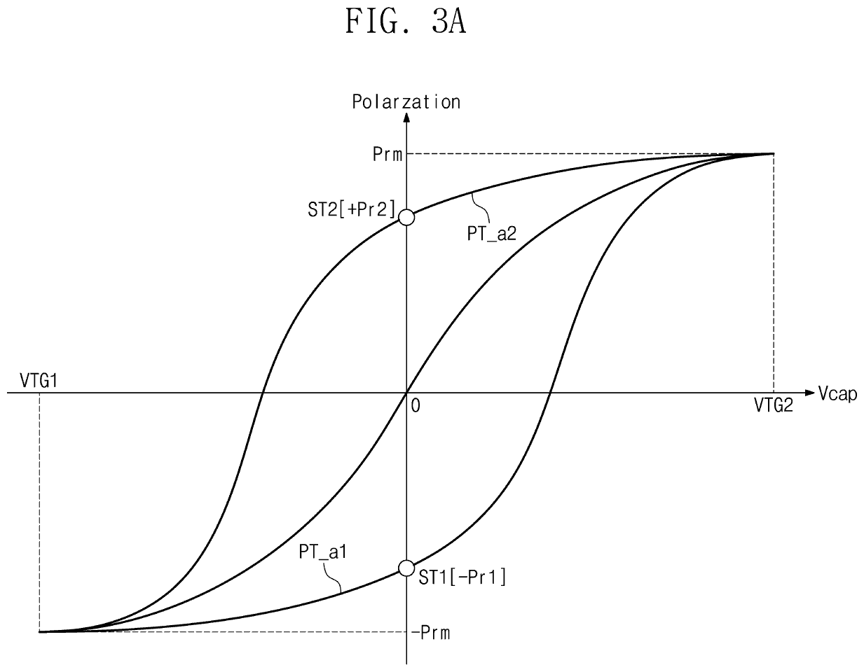

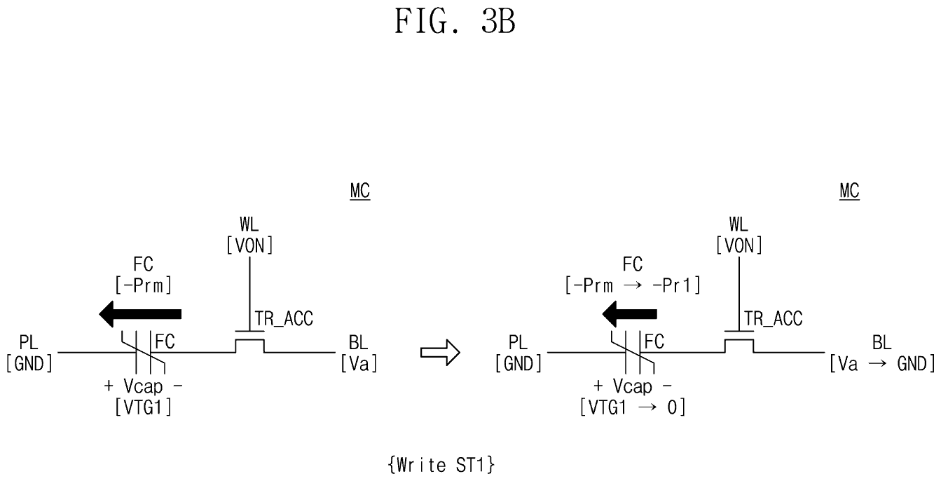

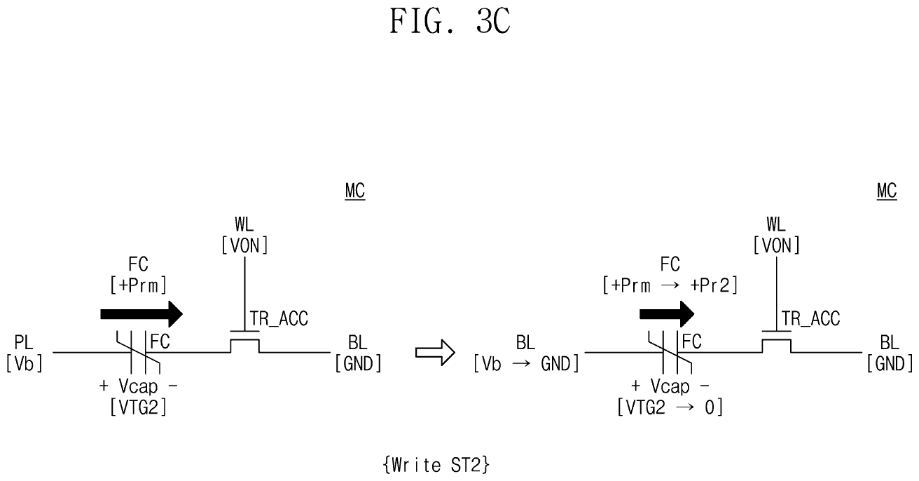

Referring to FIGS. 1 and 2, the memory cell MC may include an access transistor TR_ACC and a ferroelectric capacitor FC. The access transistor TR_ACC may be connected between the ferroelectric capacitor FC and the bit line BL. A gate of the access transistor TR_ACC may be connected to the word line WL. The access transistor TR may operate in response to a voltage of the word WL. For example, when a turn-on voltage VON (refer to FIG. 3B) is applied to the word line WL, the access transistor TR_ACC may be turned on, and thus, the ferroelectric capacitor FC may have a terminal that is electrically connected to the bit line BL.

As shown, the ferroelectric capacitor FC may be connected between the plate line PL and the access transistor TR_ACC. The ferroelectric capacitor FC may include a ferroelectric material, an antiferroelectric material, a paraelectric material, or a dielectric layer formed of a combination thereof. In an embodiment, the ferroelectric material may include a perovskite material such as BaTiOx, a hafnium (Hf)-based fluoride material, and an HfxZr1-xOy material. The antiferroelectric material may include materials such as ZrO2, HfxZr1-xOy, PbZrO3, and NaNbO3. The ferroelectric or antiferroelectric material may be a hafnium (Hf)-based fluoride material or may include a La-based rare earth element in an HfxZr1-xOy material. The ferroelectric or antiferroelectric material may include hafnium oxide. The paraelectric material may include high dielectric materials such as BeO2, MaO2, CaO2, SrO2, Al2O3, Y2O3, Sc203, La2O3, HfO2,ZrO2, TiO2, Ta2O5, Nb205, V205, SrTiO3, and BaSrTiO3.

In an embodiment, the ferroelectric capacitor FC may include a dielectric layer formed of a ferroelectric material. In this case, the polarization state or the polarization value of the ferroelectric capacitor FC may vary depending on a voltage Vcap across its terminals. Moreover, even when the across voltage Vcap is blocked, the ferroelectric capacitor FC may maintain the polarization state or the polarization value during a given time. The polarization state or the polarization value of the ferroelectric capacitor FC may be set or adjusted differently depending on data or information to be stored in the memory cell MC. In this case, a plurality of data or a plurality of information may be stored in the memory cell MC.

FIGS. 3A to 3C are diagrams for describing a 2-level write operation on a memory cell. In the embodiment, in the graph of FIG. 3A, the horizontal axis represents the across voltage Vcap of the ferroelectric capacitor FC, and the vertical axis represents the polarization state or the polarization value of the ferroelectric capacitor FC. For convenience of description, it is assumed that the memory cell MC is a memory cell including the ferroelectric capacitor FC described with reference to FIG. 2. The polarization state of the ferroelectric capacitor FC may be expressed by a negative number or a positive number, and it may be understood that the negative number or the positive number of the polarization state indicates the directionality of the polarization state of the ferroelectric capacitor FC.

Referring to FIGS. 2, 3A, 3B, and 3C, as illustrated in FIG. 3A, the polarization state of the ferroelectric capacitor FC included in the memory cell MC may change depending on the across voltage Vcap. In this case, the polarization state of the ferroelectric capacitor FC has a hysteresis characteristic according to the across voltage Vcap. Accordingly, in a state where the across voltage Vcap is 0 volts (V), the polarization state of the ferroelectric capacitor FC may be set to a first state ST1 (along a lower hysteresis curve) or it may be set to a second state ST2 (along an upper hysteresis curve).

As an example, a first target voltage VTG1 may be applied as the across voltage Vcap of the ferroelectric capacitor FC, and then, the across voltage Vcap of the ferroelectric capacitor FC may increase from the first target voltage VTG1 to 0 V. In this case, the polarization state of the ferroelectric capacitor FC may be set to a first polarization state −Pr1 (or the first state ST1).

For example, as illustrated in FIG. 3B, the turn-on voltage VON may be applied to the word line WL of the memory cell MC, a ground voltage GND may be applied to the plate line PL, and an a-th voltage Va may be applied to the bit line BL. The across voltage Vcap of the ferroelectric capacitor FC is a difference between the voltage of the plate line PL and the voltage of the bit line BL (and, by ignoring any relatively small drain-to-source voltage drop across the access transistor TR_ACC when turned on). In this case, the across voltage Vcap may be −Va, and −Va may correspond to the first target voltage VTG1. According to the above condition, the polarization state of the ferroelectric capacitor FC may be changed to a saturation polarization state −Prm.

Afterwards, the voltage of the bit line BL may decrease from the a-th voltage Va to the ground voltage GND. In this case, the across voltage Vcap may increase from the first target voltage VTG1 to 0 V. Accordingly, the polarization state of the ferroelectric capacitor FC may be changed from the saturation polarization state −Prm to the first polarization state −Pr1 along an a1-th path PT_a1. That the polarization state of the ferroelectric capacitor FC has the first polarization state −Pr1 may correspond to the memory cell MC has the first state ST1.

As an example, a second target voltage VTG2 may be applied as the across voltage Vcap of the ferroelectric capacitor FC, and then, the across voltage Vcap of the ferroelectric capacitor FC may decrease from the second target voltage VTG2 to 0 V. Accordingly, the polarization state of the ferroelectric capacitor FC may be set to a second polarization state +Pr2 (or the second state ST2).

For example, as illustrated in FIG. 3C, the turn-on voltage VON may be applied to the word line WL of the memory cell MC, a b-th voltage Vb may be applied to the plate line PL, and the ground voltage GND may be applied to the bit line BL. In this case, the across voltage Vcap of the ferroelectric capacitor FC may be Vb, and Vb may correspond to the second target voltage VTG2. According to the above condition, the polarization state of the ferroelectric capacitor FC may be changed to a saturation polarization state +Prm. Thereafter, the voltage of the plate line PL may decrease from the b-th voltage Vb to the ground voltage GND. In this case, the across voltage Vcap of the ferroelectric capacitor FC may be changed from the second target voltage VTG2 to 0 V, and thus, the polarization state of the ferroelectric capacitor FC may be changed from the saturation polarization state +Prm to the second polarization state +Pr2 along has the second polarization state +Pr2, the memory cell MC may support the second state ST2 in nonvolatile manner. As described above, the write operation on the 2-level information (e.g., the first state ST1 and the second state ST2) may be performed by differently setting the polarization state of the ferroelectric capacitor FC, by advantageously using the hysteresis characteristic of the ferroelectric capacitor FC.

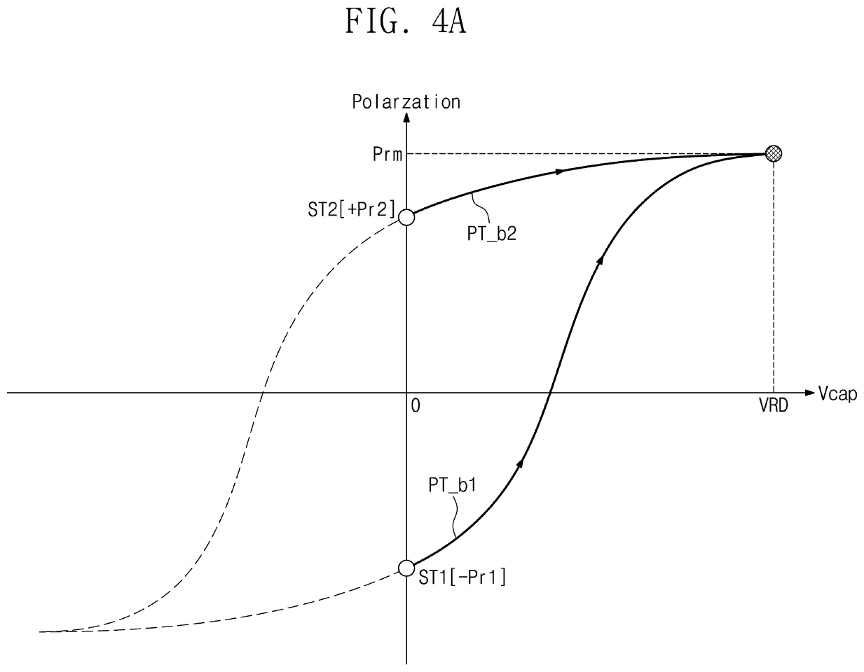

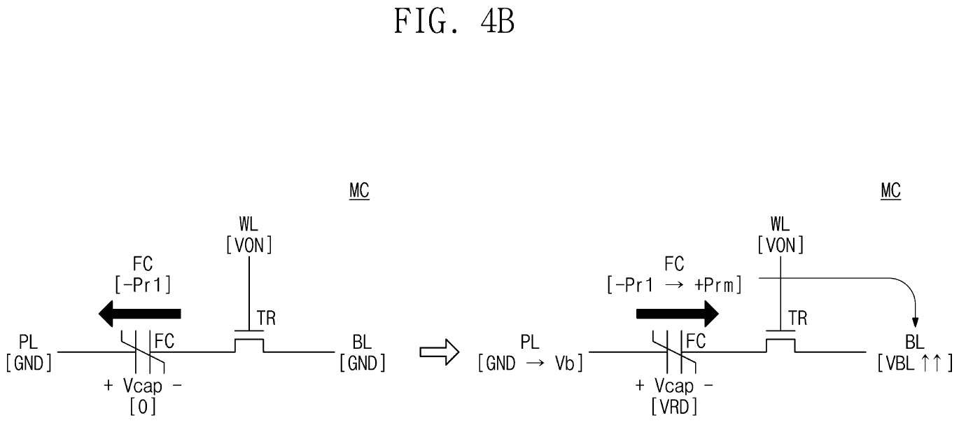

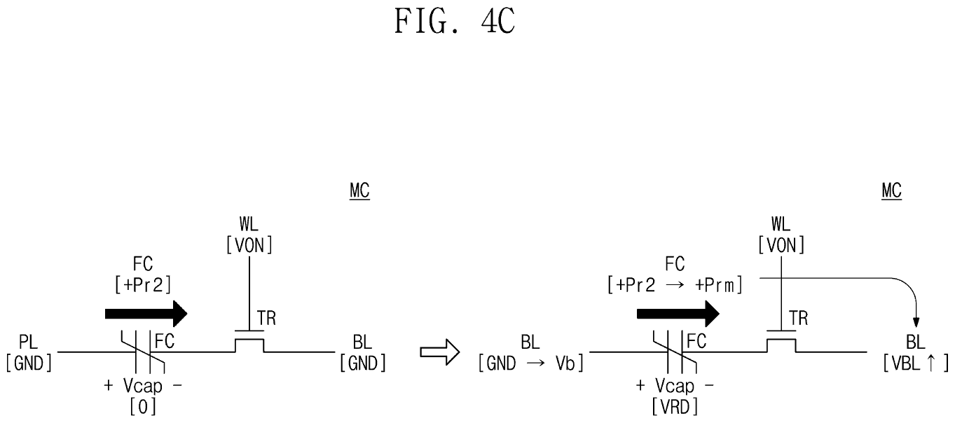

FIGS. 4A to 4C are diagrams for describing a 2-level read operation on a memory cell of FIG. 2. In the graph of FIG. 4A, the horizontal axis represents the across voltage Vcap of the ferroelectric capacitor FC, and the vertical axis represents the polarization value of the ferroelectric capacitor FC. Referring to FIGS. 2, 4A, 4B, and 4C, after the write operation described with reference to FIGS. 3A to 3C, the memory cell MC may have any one of the first state ST1 and the second state ST2. When the memory cell MC is in the first state ST1, the polarization state of the ferroelectric capacitor FC may be the first polarization state −Pr1; when the memory cell MC is in the second state ST2, the polarization state of the ferroelectric capacitor FC may be the second polarization state +Pr2.

To perform the 2-level read operation on the memory cell MC, a read voltage VRD may be applied as the across voltage Vcap of the ferroelectric capacitor FC. In an embodiment, the read voltage VRD may be a positive voltage corresponding to a saturation voltage. The read voltage VRD may correspond to the second target voltage VTG2 described with reference to FIG. 3A. As the read voltage VRD is applied as the across voltage Vcap of the ferroelectric capacitor FC, the polarization state of the ferroelectric capacitor FC may be changed. The amount of released charges may differ depending on a changed magnitude of the polarization state of the ferroelectric capacitor FC.

For example, as illustrated in FIG. 4B, the memory cell MC may be in the first state ST1. That is, when the ground voltage GND is applied to each of the plate line PL and the bit line BL, the polarization state of the ferroelectric capacitor FC may be the first polarization state −Pr1. In this case, the b-th voltage Vb may be applied to the plate line PL. According to the above bias condition, the across voltage Vcap of the ferroelectric capacitor FC may increase to the b-th voltage Vb. The b-th voltage Vb may correspond to the read voltage VRD. As the across voltage Vcap of the ferroelectric capacitor FC increases to the read voltage VRD, the polarization state of the ferroelectric capacitor FC may be changed from the first polarization state −Pr1 to the saturation polarization state +Prm along a b1-th path PT_b1 of FIG. 4A. As the polarization state of the ferroelectric capacitor FC is changed from the first polarization state −Pr1 to the saturation polarization state +Prm, a bit line voltage VBL may be increased as much as a first magnitude (VBL 11).

Alternatively, as illustrated in FIG. 4C, the memory cell MC may be in the second state ST2. That is, when the ground voltage GND is applied to each of the plate line PL and the bit line BL, the polarization state of the ferroelectric capacitor FC may be the second polarization state +Pr2. In this case, the b-th voltage Vb may be applied to the plate line PL. According to the above bias condition, the across voltage Vcap of the ferroelectric capacitor FC may increase to the b-th voltage Vb. The b-th voltage Vb may correspond to the read voltage VRD. As the across voltage Vcap of the ferroelectric capacitor FC increases to the read voltage VRD, the polarization state of the ferroelectric capacitor FC may be changed from the second polarization state +Pr2 to the saturation polarization state +Prm along a b2-th path PT_b2 of FIG. 4A. As the polarization state of the ferroelectric capacitor FC is changed from the second polarization state +Pr2 to the saturation polarization state +Prm, the bit line voltage VBL may be increased as much as a second magnitude (VBL 1).

In an embodiment, the variance or the increment of the bit line voltage VBL may differ depending on the variance of the polarization state of the ferroelectric capacitor

FC. For example, when the polarization state of the ferroelectric capacitor FC is changed from the first polarization state −Pr1 to the saturation polarization state +Prm, the bit line voltage VBL may be increased as much as the first magnitude (VBL 11). When the polarization state of the ferroelectric capacitor FC is changed from the second polarization state +Pr2 to the saturation polarization state +Prm, the bit line voltage VBL may be increased as much as the second magnitude (VBL 1). In this case, the first magnitude (VBL 11) may be greater than the second magnitude (VBL 1). That is, in the read operation, the variance of the bit line voltage VBL may differ depending on the state of the memory cell MC or the polarization state of the ferroelectric capacitor FC, and the state of the memory cell MC may be determined by sensing the variance of the bit line voltage VBL.

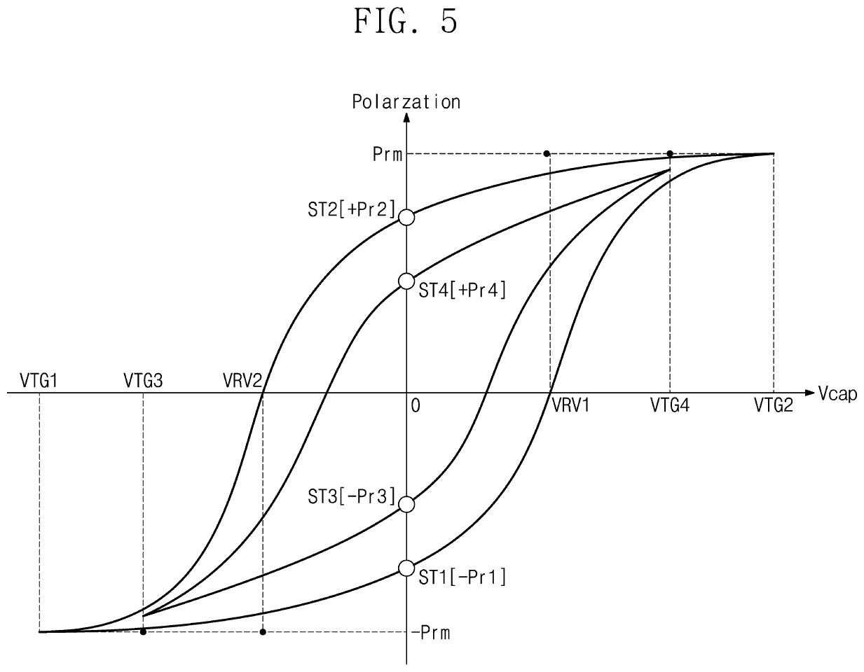

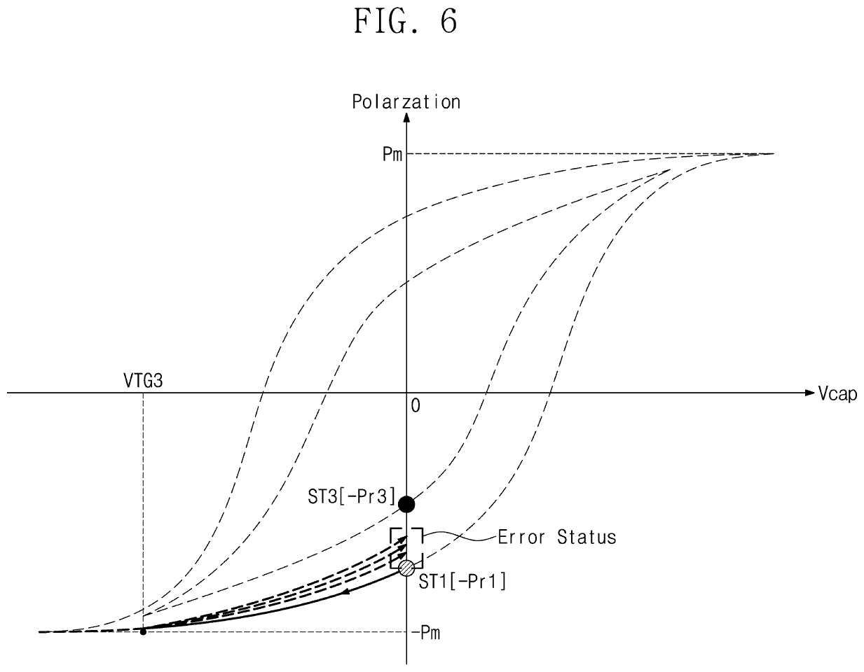

FIGS. 5 and 6 are diagrams for describing a multi-level operation of a memory device of FIG. 1. In the graphs of FIGS. 5 and 6, the horizontal axis represents the across voltage Vcap of the ferroelectric capacitor FC, and the vertical axis represents the polarization state of the ferroelectric capacitor FC.

Below, for convenience, the description will be given as the polarization state of the ferroelectric capacitor FC is symmetrical with respect to the across voltage Vcap. In this case, a stabilization operation for the polarization state of the ferroelectric capacitor FC may be accomplished by setting the across voltage Vcap to 0 V. However, the present disclosure is not limited thereto. For example, the polarization state of the ferroelectric capacitor FC may be asymmetrical with respect to the across voltage Vcap; in this case, the across voltage Vcap for the stabilization operation may not be 0 V.

Referring to FIGS. 2, 5, and 6, through the write operation, the memory cell MC may have one of first to fourth states ST1, ST2, ST3, and ST4. The memory cell MC described with reference to FIGS. 3A to 4C has one of only two states ST1 and ST2 through the write operation. In contrast, in the embodiment of FIG. 5, through the write operation, the memory cell MC may have one of the first to fourth states ST1, ST2, ST3, and ST4. In this case, because more information or data are stored in one memory cell MC, the area of the memory device 100 for storing data of the same size may decrease, or more information or data may be stored in the memory device 100 of the same area. In an embodiment, an operation of writing the first state ST1 in the memory cell MC may be similar to that described with reference to FIG. 3B. For example, as the first target voltage VTG1 and 0 V are sequentially applied as the across voltage Vcap of the ferroelectric capacitor FC of the memory cell MC, the polarization state of the ferroelectric capacitor FC of the memory cell MC may be set to the first polarization state −Pr1.

In an embodiment, an operation of writing the second state ST2 in the memory cell MC may be similar to that described with reference to FIG. 3C. For example, as the second target voltage VTG2 and 0 V are sequentially applied as the across voltage Vcap of the ferroelectric capacitor FC of the memory cell MC, the polarization state of the ferroelectric capacitor FC of the memory cell MC may be set to the second polarization state +Pr2. In an embodiment, as illustrated in FIG. 5, the polarization state of the ferroelectric capacitor FC has the hysteresis characteristic depending to the across voltage Vcap. In this case, ferroelectric materials included in the ferroelectric capacitor FC may be in a polymorphic form. Accordingly, the ferroelectric materials have the sub-loop characteristic that the polarization state is switched only in some domains at a voltage less than a saturation voltage (e.g., VCC). Paths respectively corresponding to the third and fourth states ST3 and ST4 may be formed depending on the sub-loop characteristic, and the polarization state of the ferroelectric capacitor FC may be set to a third polarization state −Pr3 and a fourth polarization state +Pr4 respectively corresponding to the third and fourth states ST3 and ST4 through the paths.

As an example, in a state where the polarization state of the ferroelectric capacitor FC is “0”, as a third target voltage VTG3 and 0 V are sequentially applied as the across voltage Vcap of the ferroelectric capacitor FC of the memory cell MC, the polarization state of the ferroelectric capacitor FC of the memory cell MC may be set to the third polarization state −Pr3. However, a current state of the memory cell MC may be variously set; in this case, even though the third target voltage VTG3 and 0 V are sequentially applied as the across voltage Vcap, the polarization state of the ferroelectric capacitor FC of the memory cell MC may be set to the third polarization state −Pr3 depending on the current state of the memory cell MC. For example, as illustrated in FIG. 6, it is assumed that the memory cell MC having the first state ST1 is written to the third state ST3. Under the assumption, as described above, the third target voltage VTG3 and 0 V may be sequentially applied as the across voltage Vcap. In this case, depending on the hysteresis characteristic of the ferroelectric capacitor FC, the polarization state of the ferroelectric capacitor FC is set to be lower in value than the third polarization state −Pr3. This means that the memory cell MC is not normally written to the third state ST3. That is, the memory cell MC may have an error state.

As described above, due to the hysteresis characteristic of the ferroelectric capacitor FC, the write operation on specific states (e.g., ST3 and ST4) may not be normally performed depending on the current state of the memory cell MC. In an embodiment, the specific states may indicate states not corresponding to the saturation polarization state of the ferroelectric capacitor FC. In this case, there may be required a method of performing sensing for the current state of the memory cell MC and differently controlling the across voltage depending on the current state of the memory cell MC. However, the above method may require the operation of sensing the current state of the memory cell MC, thereby causing the reduction of performance of the memory device 100.

According to an embodiment of the present disclosure, the write operation on a plurality of states may be normally performed regardless of the current state of the memory cell MC. For example, an operation of writing the third state ST3 or the fourth state ST4 in the memory cell MC may advantageously include: (i) a polarization removing operation, (ii) a target state setting operation, and (iii) a stabilization operation of the memory cell MC, as explained more fully hereinbelow.

As an example, in the case of writing the third state ST3 in the memory cell MC, a first removing voltage VRV1, the third target voltage VTG3, and 0 V may be sequentially applied as the across voltage Vcap of the ferroelectric capacitor FC. In this case, the third state ST3 may be normally written in the memory cell MC regardless of the current state of the memory cell MC.

In detail, the first removing voltage VRV1 may refer to a voltage for removing (i.e., clearing/resetting) a remanent polarization of the ferroelectric capacitor FC. When the memory cell MC is in the first state ST1, the polarization state of the ferroelectric capacitor FC of the memory cell MC may be changed to “0” by the first removing voltage VRV1. Afterwards, when the third target voltage VTG3 and 0 V are sequentially applied as the across voltage Vcap, the polarization state of the ferroelectric capacitor FC may be set to the third polarization state −Pr3. When the memory cell MC is in the second state ST2 or the fourth state ST4, as the first removing voltage VRV1, the third target voltage VTG3, and 0 V are sequentially applied, the polarization state of the ferroelectric capacitor FC may be set to the third polarization state −Pr3.

As an example, in the case of writing the fourth state ST4 in the memory cell MC, a second removing voltage VRV2, a fourth target voltage VTG4, and 0 V may be sequentially applied as the across voltage Vcap of the ferroelectric capacitor FC. The operation of writing the fourth state ST4 in the memory cell MC is similar to that described above, and thus, additional description will be omitted to avoid redundancy. Accordingly, a specific state may be normally written in the memory cell MC regardless of the current state of the memory cell MC. The write operation according to an embodiment of the present disclosure will be described in detail with reference to the following drawings.

Below, to describe embodiments of the present disclosure easily, the memory cell MC may have one of the first to fourth states ST1 to ST4, and the first to fourth states ST1 to ST4 may respectively correspond to the first to fourth polarization states—Pr1, +Pr2, −Pr3, and +Pr4 of the ferroelectric capacitor FC, as shown by the vertical axis in FIG. 5. Below, the expression “a positive number/a negative number of the polarization state” may be understood as indicating the directivity of the polarization state of the ferroelectric capacitor FC. That is, that the polarization state of the ferroelectric capacitor FC is expressed by a positive number (+) may mean that the polarization state of the ferroelectric capacitor FC has a first directivity; that the polarization state of the ferroelectric capacitor FC is expressed by a negative number (−) may mean that the polarization state of the ferroelectric capacitor FC has a second directivity opposite to the first directivity. The absolute value (e.g., Pr1, Pr2, Pr3, Pr4, or Prm) of the polarization state may be understood as indicating the magnitude of the polarization state.

In this case, the first polarization state −Pr1 may correspond to a value at which the ferroelectric capacitor FC is stabilized from the negative saturation state −Prm. That is, the first polarization state −Pr1 may correspond to a polarization state of the case where the across voltage Vcap of the ferroelectric capacitor FC increases from the first “negative” target voltage VTG1 to 0 V. The second polarization state +Pr2 may correspond to a value at which the ferroelectric capacitor FC is stabilized from the positive saturation state +Prm. That is, the second polarization state +Pr2 may correspond to a polarization state of the case where the across voltage Vcap of the ferroelectric capacitor FC decreases from the second “highest” positive target voltage VTG2 to 0 V. The third polarization state −Pr3 may correspond to a value at which the ferroelectric capacitor FC is stabilized from a specific negative saturation state. That is, the third polarization state −Pr3 may correspond to a polarization state of the case where the across voltage Vcap of the ferroelectric capacitor FC increases from the third “negative” target voltage VTG3 to 0 V. Finally, the fourth polarization state +Pr4 may correspond to a value at which the ferroelectric capacitor FC is stabilized from a specific positive saturation state. That is, the fourth polarization state +Pr4 may correspond to a polarization state of the case where the across voltage Vcap of the ferroelectric capacitor FC decreases from the fourth target voltage VTG4 to 0 V.

In an embodiment, the first and second removing voltages VRV1 and VRV2 may be determined based on a path corresponding to the positive saturation state or the negative saturation state of the ferroelectric capacitor FC. For example, the first removing voltage VRV1 may be used to remove the remanent polarization of the ferroelectric capacitor FC of the memory cell MC in the operation of writing the third state ST3 in the memory cell MC. The third state ST3 may correspond to the third polarization state −Pr3. In this case, the first removing voltage VRV1 may correspond to the across voltage Vcap at which the polarization state becomes “0” on a path (i.e., a lower limit path) corresponding to the negative saturation state −Prm of the same polarization direction as the third polarization state −Pr3. In the graph of FIG. 5, the first removing voltage VRV1 may correspond to a crosspoint at which the polarization state of the ferroelectric capacitor FC and the horizontal axis of a lower limit curve cross. Alternatively, the first removing voltage VRV1 may have a level greater than or equal to the crosspoint at which the polarization state of the ferroelectric capacitor FC and the horizontal axis of the lower limit curve cross. Alternatively, the first removing voltage VRV1 may be greater than or equal to a minimum voltage at which a polarization direction of a polarization state (e.g., −Pr1) whose absolute value is greater than the absolute value (i.e., Pr3) of the third polarization state −Pr3 is switched in the same polarization direction as the third polarization state −Pr3.

In contrast, the second removing voltage VRV2 may be used to remove the remanent polarization of the ferroelectric capacitor FC of the memory cell MC in the operation of writing the fourth state ST4 in the memory cell MC. The fourth state ST4 may correspond to the fourth polarization state +Pr4. In this case, the first removing voltage VRV2 may correspond to the across voltage Vcap at which the polarization state becomes “0” on a path (i.e., an upper limit path) corresponding to the positive saturation state of the same polarization direction as the fourth polarization state +Pr4. In the graph of FIG. 5, the second removing voltage VRV2 may correspond to a crosspoint at which the polarization state of the ferroelectric capacitor FC and the horizontal axis of an upper limit curve cross. Alternatively, the second removing voltage VRV2 may have a level greater than or equal to the crosspoint at which the polarization state of the ferroelectric capacitor FC and the horizontal axis of the upper limit curve cross. Alternatively, the second removing voltage VRV2 may be greater than or equal to a minimum voltage at which a polarization direction of a certain polarization state (e.g., +Pr2), whose polarization direction is the same with that of the fourth polarization +Pr4 and whose absolute value is greater than the absolute value (i.e., Pr4) of the fourth polarization state +Pr4, is switched

The levels of the voltages described above may be compared to describe embodiments of the present disclosure easily, and the level of each voltage may be variously changed and modified depending on a characteristic of the ferroelectric capacitor FC, a way to implement the memory cell MC, or a way to implement the memory device 100.

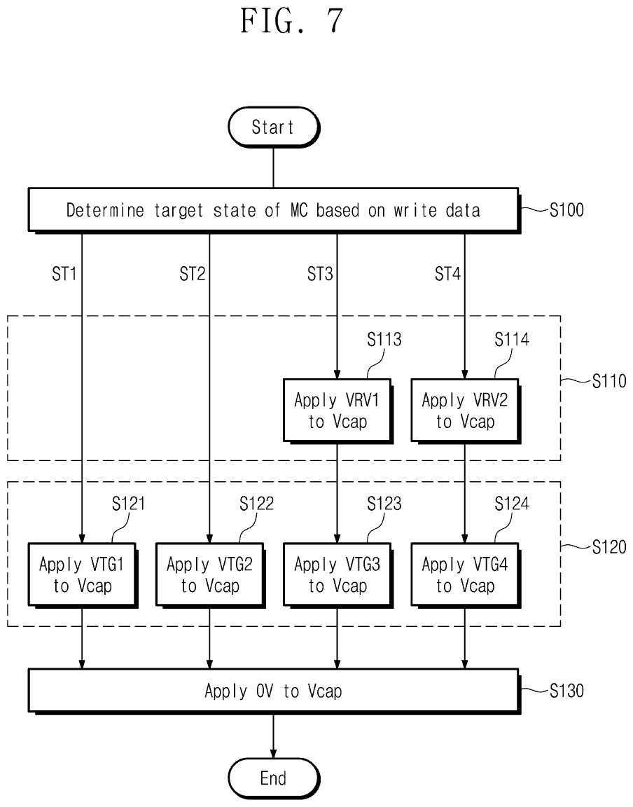

FIG. 7 is a flowchart illustrating an operation of a memory device configured to perform a 4-level write operation described with reference to FIG. 5. Referring to FIGS. 1, and 5-7, in operation S100, the memory device 100 may determine a target state of the memory cell MC based on write data. The memory device 100 may perform the polarization removing operation in operation S110 and the target state setting operation in operation S120, based on the target state of the memory cell MC.

In an embodiment, the polarization removing operation in operation S110 may indicate an operation of removing the remanent polarization of the ferroelectric capacitor FC of the memory cell MC, and the target state setting operation in operation S120 may indicate an operation of setting the polarization state of the ferroelectric capacitor FC of the memory cell MC to a polarization state corresponding to the determined target state.

When the determined target state is the first state ST1, in operation S121, the memory device 100 may apply the first target voltage VTG1 as the across voltage Vcap. In an embodiment, the first polarization state −Pr1 corresponding to the first state ST1 may have the smallest value among values of polarization states corresponding to the first to fourth states ST1 to ST4, and the first target voltage VTG1 may be a negative saturation voltage (e.g., −VCC). In an embodiment, the negative saturation voltage −VCC may indicate the across voltage Vcap by which the polarization state of the ferroelectric capacitor FC is changed to the negative saturation state −Prm.

Alternatively, when the determined target state is the second state ST2, in operation S122, the memory device 100 may apply the second target voltage VTG2 as the across voltage Vcap. In an embodiment, the second polarization state +Pr2 corresponding to the second state ST2 may have the greatest value among the values of the polarization states corresponding to the first to fourth states ST1 to ST4, and the second target voltage VTG2 may be a positive saturation voltage (e.g., +VCC).

Next, when the determined target state is the third state ST3, in operation S113, the memory device 100 may apply the first removing voltage VRV1 as the across voltage Vcap. Afterwards, in operation S123, the memory device 100 may apply the third target voltage VTG3 as the across voltage Vcap. In an embodiment, the third polarization state −Pr3 corresponding to the third state ST3 may have the second smallest value among the values of the polarization states corresponding to the first to fourth states ST1 to ST4, and the third target voltage VTG3 may be greater than the negative saturation voltage −VCC and may be less than 0 V or the ground voltage GND. In an embodiment, the first removing voltage VRV1 may be greater than 0 V or the ground voltage GND and may be less than or equal to the positive saturation voltage +VCC.

When the determined target state is the fourth state ST4, in operation S114, the memory device 100 may apply the second removing voltage VRV2 as the across voltage Vcap. Afterwards, in operation S124, the memory device 100 may apply the fourth target voltage VTG4 as the across voltage Vcap. In an embodiment, the fourth polarization state +Pr4 corresponding to the fourth state ST4 may have the second greatest value among the values of the polarization states corresponding to the first to fourth states ST1 to ST4, and the fourth target voltage VTG4 may be greater than the 0 V or the ground voltage GND and may be less than the positive saturation voltage +VCC. In an embodiment, the second removing voltage VRV2 may be less than 0 V or the ground voltage GND and may be greater than or equal to the negative saturation voltage −VCC.

Through operation S110, the remanent polarization of the ferroelectric capacitor FC of the memory cell MC may be advantageously removed; through operation S120, the polarization state of the ferroelectric capacitor FC of the memory cell MC may be set to a value corresponding to the target state.

Afterwards, in operation S130, the memory device 100 may apply 0 V as the across voltage Vcap. In an embodiment, as 0 V is applied as the across voltage Vcap, the polarization state of the ferroelectric capacitor FC of the memory cell MC may be stabilized at the value corresponding to the target state. In some embodiments, the polarization state of the ferroelectric capacitor FC may be relatively symmetrical with respect to 0 V of the across voltage Vcap. In this case, as described above, as 0 V is applied as the across voltage Vcap, the polarization state of the ferroelectric capacitor FC may be stabilized. However, the present disclosure is not limited thereto. For example, the polarization state of the ferroelectric capacitor FC may be asymmetrical with respect to the across voltage Vcap. Alternatively, as a stabilization voltage is applied as the across voltage Vcap, the polarization state of the ferroelectric capacitor FC may be stabilized; in this case, the stabilization voltage may be 0 V, a negative voltage, or a positive voltage depending on the characteristic of the ferroelectric capacitor FC.

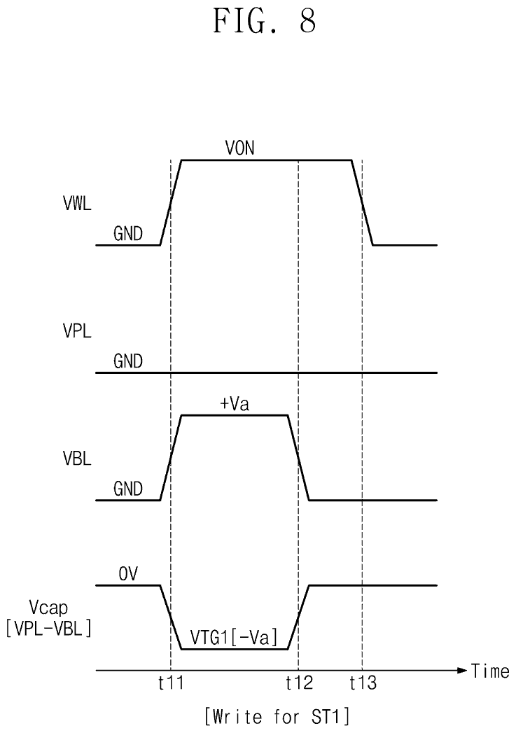

FIGS. 8 to 11D are diagrams for describing an operation according to the flowchart of FIG. 7. An example in which the memory device 100 simultaneously controls the bit line voltage VBL, a plate line voltage VPL, or a word line voltage VWL at a specific time point is illustrated in the following drawings. However, as will be understood by those skilled in the art, the memory device 100 may individually control the bit line voltage VBL, the plate line voltage VPL, or the word line voltage VWL with a given time interval, or the voltage of the bit line voltage VBL, the plate line voltage VPL, or the word line voltage VWL may not be simultaneously controlled. The word line voltage VWL may indicate a voltage level of the word line WL connected to the memory cell MC, the plate line voltage VPL may indicate a voltage level of the plate line PL connected to the memory cell MC, and the bit line voltage VBL may indicate a voltage level of the bit line BL connected to the memory cell MC. The across voltage Vcap may indicate a voltage across the ferroelectric capacitor FC. Moreover, when the word line voltage VWL is the turn-on voltage VON, the across voltage Vcap may be expressed or simplified by a difference between a plate line voltage and a bit line voltage (i.e., VPL −VBL).

First, the write operation on the first state ST1 will be described with reference to FIG. 8. In the timing diagram of FIG. 8, the horizontal axis represents a time, and the vertical axis represents the word line voltage VWL, the plate line voltage VPL, the bit line voltage VBL, and the across voltage Vcap. Referring to FIGS. 1, 7, and 8, the memory device 100 may write the first state ST1 into the memory cell MC. For example, during a time period from t11 to t13, the memory device 100 may apply the turn-on voltage VON as the word line voltage VWL. In an embodiment, the turn-on voltage VON may be a high voltage enough to turn on the access transistor TR_ACC of the memory cell MC.

Also, during the time period from t11 to t13, the memory device 100 may apply the ground voltage GND as the plate line voltage VPL. During a time period from t11 to t12, the memory device 100 may apply the a-th voltage Va as the bit line voltage VBL. In this case, during the time period from t11 to t12, the across voltage Vcap may be −Va in magnitude. As an example, −Va may correspond to the first target voltage VTG1. As an example, −Va may correspond to the negative saturation voltage −VCC. In response to the first target voltage VTG1, the polarization state of the ferroelectric capacitor FC may have the saturation polarization state −Prm (Corresponding to operation S121 of FIG. 7).

During a time period from t12 to t13, the memory device 100 may apply the ground voltage GND as the bit line voltage VBL. In this case, the across voltage Vcap may be 0 V. Because the polarization state of the ferroelectric capacitor FC is set to the saturation polarization state −Prm during the time period from t11 to t12, then during the time period from t12 to t13, the polarization state of the ferroelectric capacitor FC may be stabilized to the first polarization state −Pr1 in response to the across voltage Vcap of 0 V (corresponding to operation S130 of FIG. 7).

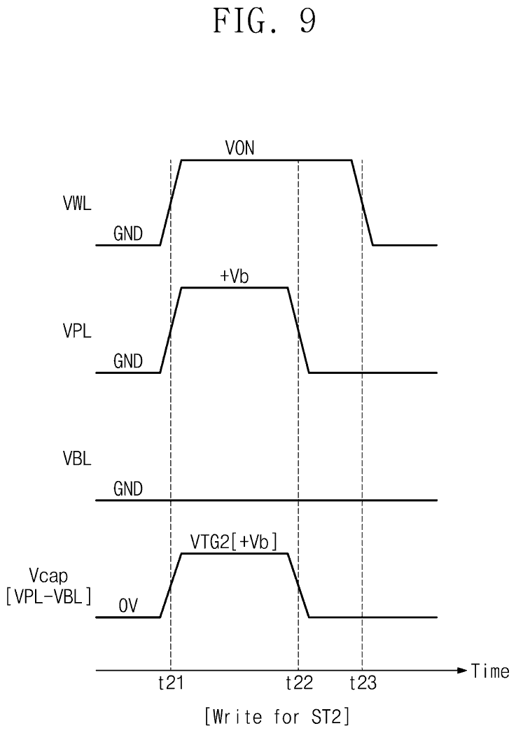

Next, the write operation on the second state ST2 will be described with reference to FIG. 9. In the timing diagram of FIG. 9, the horizontal axis represents a time, and the vertical axis represents the word line voltage VWL, the plate line voltage VPL, the bit line voltage VBL, and the across voltage Vcap. Referring to FIGS. 1, 7, and 9, the memory device 100 may write the second state ST2 in the memory cell MC.

During a time period from t21 to t23, the memory device 100 may apply the turn-on voltage VON as the word line voltage VWL. In an embodiment, the turn-on voltage VON may be a high voltage enough to turn on the access transistor TR_ACC of the memory cell MC. Also, during the time period from t21 to t23, the memory device 100 may apply the ground voltage GND as the bit line voltage VBL.

Furthermore, during a time period from t21 to t22, the memory device 100 may apply the b-th voltage +Vb as the plate line voltage VPL. In this case, during the time period from t21 to t22, the across voltage Vcap of the ferroelectric capacitor FC of the memory cell MC may be +Vb in magnitude. As an example, +Vb may correspond to the second target voltage VTG2. As an example, +Vb may correspond to the positive saturation voltage +VCC. In response to the second target voltage VTG2, the polarization state of the ferroelectric capacitor FC may have the saturation polarization state +Prm (corresponding to operation S122 of FIG. 7).

During the time period from t22 to t23, the memory device 100 may apply the ground voltage GND as the plate line voltage VPL. In this case, the across voltage Vcap may be 0 V. Because the polarization state of the ferroelectric capacitor FC is set to the saturation polarization state +Prm during the time period from t21 to t22, during the time period from t22 to t23, the polarization state of the ferroelectric capacitor FC may be stabilized to the second polarization state +Pr2 in response to the across voltage Vcap of 0 V (corresponding to operation S130 of FIG. 7).

In an embodiment, the write operation on the first state ST1 and the second state ST2 of the memory device 100 may be accomplished through stabilization after setting the polarization state of the ferroelectric capacitor FC of the memory cell MC to the negative saturation state or the positive saturation state. Accordingly, the write operation on the first state ST1 and the second state ST2 of the memory device 100 may be normally performed regardless of the current state of the memory cell MC.

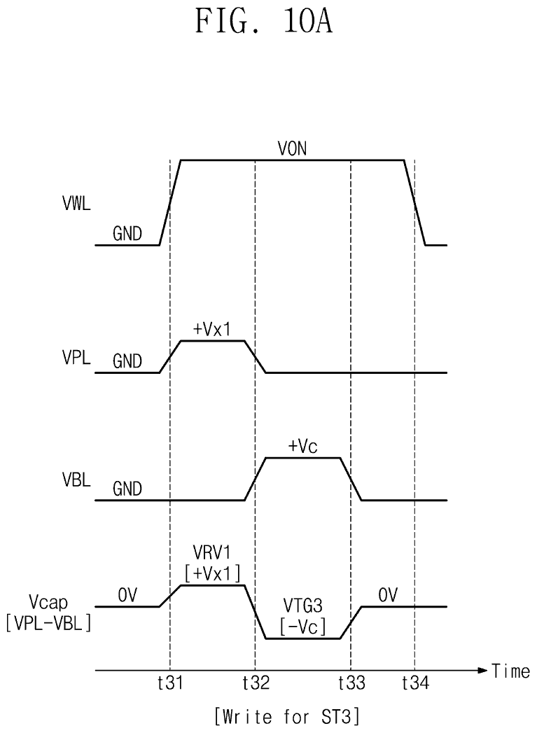

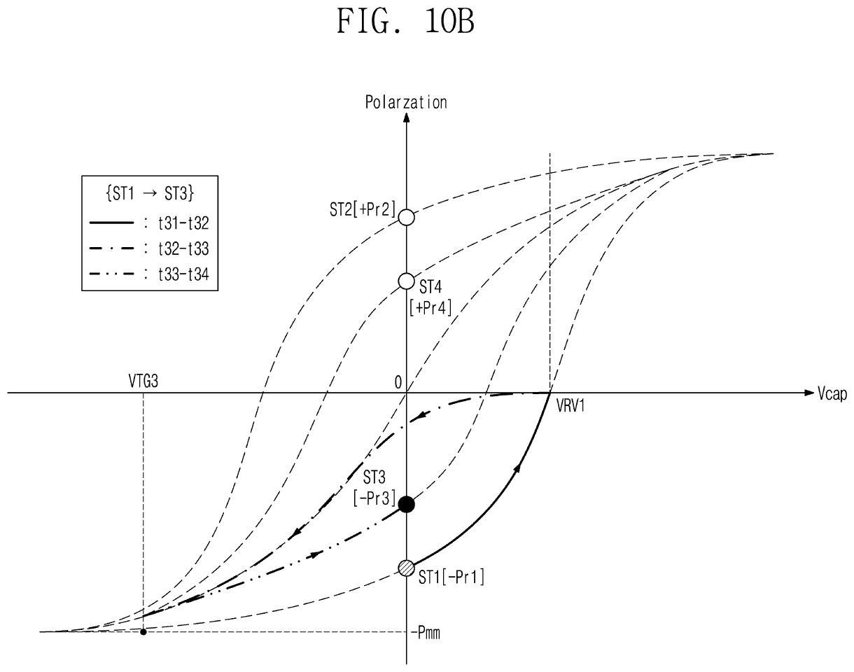

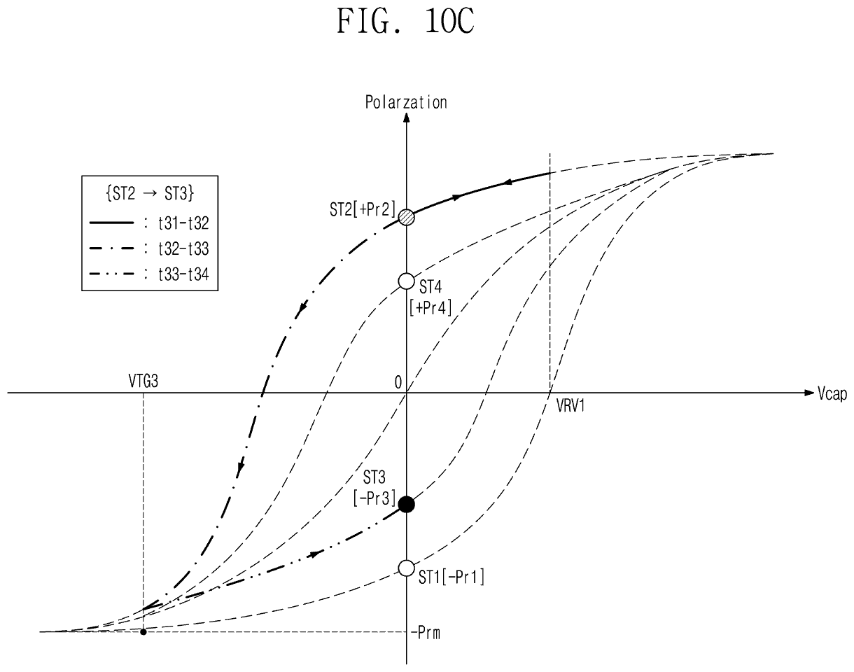

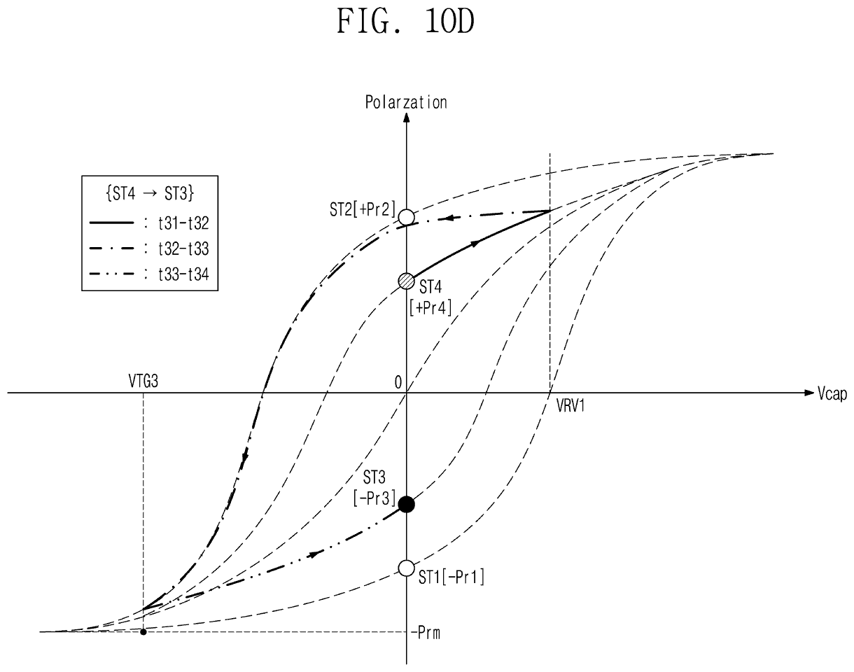

Next, the write operation on the third state ST3 will be described with reference to FIGS. 10A to 10D. In the timing diagram of FIG. 10A, the horizontal axis represents a time, and the vertical axis represents the word line voltage VWL, the plate line voltage VPL, the bit line voltage VBL, and the across voltage Vcap. In the graphs of FIGS. 10B to 10D, the horizontal axis represents the across voltage Vcap of the ferroelectric capacitor FC, and the vertical axis represents the polarization state of the ferroelectric capacitor FC.

Referring to FIGS. 1, 7, 10A, 10B, 10C, and 10D, the memory device 100 may write the third state ST3 in the memory cell MC. For example, during a time period from t31 to t34, the memory device 100 may apply the turn-on voltage VON as the word line voltage VWL. In an embodiment, the turn-on voltage VON may be a high voltage enough to turn on the access transistor TR_ACC of the memory cell MC.

During a time period from t31 to t32, the memory device 100 may apply an x1-th voltage +Vx1 as the plate line voltage VPL and may apply the ground voltage GND as the bit line voltage VBL. In this case, during the time period from t31 to t32, the across voltage Vcap may be +Vx1. As an example, +Vx1 may correspond to the first removing voltage VRV1. As an example, +Vx1 may be less than the positive saturation voltage +VCC and may be greater than the ground voltage GND. As the across voltage Vcap is changed from 0 V to the first removing voltage VRV1, the polarization state of the ferroelectric capacitor FC may increase (corresponding to operation S113 of FIG. 7).

Afterwards, during a time period from t32 to t33, the memory device 100 may maintain the plate line voltage VPL at the ground voltage GND and may apply a c-th voltage +Vc as the bit line voltage VBL. In this case, during the time period from t32 to t33, the across voltage Vcap may be −Vc. As an example, −Vc may correspond to the third target voltage VTG3. As an example, −Vc may be greater than the negative saturation voltage −VCC and may be less than the ground voltage GND. As an example, −Vc may be less than the second removing voltage VRV2. As the across voltage Vcap decreases from the first removing voltage VRV1 to the third target voltage VTG3, the polarization state of the ferroelectric capacitor FC may decrease (corresponding to operation S123 of FIG. 7).

Afterwards, during a time period from t33 to t34, the memory device 100 may maintain the plate line voltage VPL and the bit line voltage VPL at the ground voltage GND. In this case, during the time period from t33 to t34, the across voltage Vcap may be 0 V. As the across voltage Vcap increases from the third target voltage VTG3 to 0 V, the polarization state of the ferroelectric capacitor FC may be stabilized to the third polarization state −Pr3 corresponding to the third state ST3.

In an embodiment, in each time period described above, the polarization state of the ferroelectric capacitor FC may be variously changed depending on the current state of the memory cell MC or the remanent polarization state of the ferroelectric capacitor FC. However, after the time period from t33 to t34, the polarization state of the ferroelectric capacitor FC may have the third polarization state −Pr3 corresponding to the target state (i.e., the third state ST3), regardless of the current state of the memory cell MC or the remanent polarization state of the ferroelectric capacitor FC.

As an example, an operation of writing the third state ST3 into the memory cell MC when the current state of the memory cell MC is in the first state ST1, will be described with reference to FIG. 10B. First, the memory cell MC has the first state ST1. That is, when the across voltage Vcap is 0 V, the remanent polarization state of the ferroelectric capacitor FC may be the first polarization state −Pr1.

Then, during the time period from t31 to t32 of FIG. 10A, the first removing voltage VRV1 may be applied as the across voltage Vcap. In this case, due to the hysteresis characteristic, the polarization state of the ferroelectric capacitor FC may be changed to “0” along a solid line illustrated in FIG. 10B (i.e., a path corresponding to the time period from t31 to t32).

Afterwards, during the time period from t32 to t33 of FIG. 10A, the third target voltage VTG3 may be applied as the across voltage Vcap. In this case, due to the hysteresis characteristic, the polarization state of the ferroelectric capacitor FC may decrease to a value corresponding to the third target voltage VTG3 along a dash-single dotted line illustrated in FIG. 10B (i.e., a path corresponding to the time period from t32 to t33).

Afterwards, during the time period from t33 to t34 of FIG. 10A, the across voltage Vcap may be changed to 0 V. In this case, due to the hysteresis characteristic, the polarization state of the ferroelectric capacitor FC may be stabilized to the third polarization state −Pr3 corresponding to the third state ST3 along a dash-double dotted line illustrated in FIG. 10B (i.e., a path corresponding to the time period from t33 to t34).

As described with reference to FIG. 6, under the condition that the current state of the memory cell MC is the first state ST1, when the third target voltage VTG3 is applied as the across voltage Vcap, the third state ST3 may not be normally written in the memory cell MC. In contrast, as described with reference to FIG. 10B, according to an embodiment of the present disclosure, the polarization state of the ferroelectric capacitor FC may be set to the third polarization state −Pr3 corresponding to the third state ST3 by first applying the first removing voltage VRV1 as the across voltage Vcap such that a remanent polarization value of the ferroelectric capacitor FC is removed and then sequentially applying the third target voltage VTG3 and 0 V as the across voltage Vcap.

Even though the current state of the memory cell MC is the second state ST2 or the fourth state ST4, the third state ST3 may be normally written in the memory cell MC through the above operation. As an example, an operation of writing the third state ST3 in the memory cell MC in a state where the current state of the memory cell MC is the second state ST2 will be described with reference to FIG. 10C. First, the memory cell MC has the second state ST2. That is, when the across voltage Vcap is 0 V, the remanent polarization state of the ferroelectric capacitor FC may be the second polarization state +Pr2.

During the time period from t31 to t32 of FIG. 10A, the first removing voltage VRV1 may be applied as the across voltage Vcap. In this case, due to the hysteresis characteristic, the polarization state of the ferroelectric capacitor FC may increase to a value corresponding to the first removing voltage VRV1 along a solid line illustrated in FIG. 10C (i.e., a path corresponding to the time period from t31 to t32). Afterwards, during the time period from t32 to t33 of FIG. 10A, the third target voltage VTG3 may be applied as the across voltage Vcap. In this case, due to the hysteresis characteristic, the polarization state of the ferroelectric capacitor FC may decrease to a value corresponding to the third target voltage VTG3 along a dash-single dotted line illustrated in FIG. 10C (i.e., a path corresponding to the time period from t32 to t33).

Afterwards, during the time period from t33 to t34 of FIG. 10A, the across voltage Vcap is set to 0 V. In this case, due to the hysteresis characteristic, the polarization state of the ferroelectric capacitor FC may be set to the third polarization state −Pr3 corresponding to the third state ST3 along a dash-double dotted line illustrated in FIG. 10C (i.e., a path corresponding to the time period from t33 to t34).

As an example, an operation of writing the third state ST3 into the memory cell MC when the current state of the memory cell MC is the fourth state ST4, will be described with reference to FIG. 10D. First, the memory cell MC has the fourth state ST4. That is, when the across voltage Vcap is 0 V, the remanent polarization state of the ferroelectric capacitor FC may be the fourth polarization state +Pr4.

During the time period from t31 to t32 of FIG. 10A, the first removing voltage VRV1 may be applied as the across voltage Vcap. In this case, due to the hysteresis characteristic, the polarization state of the ferroelectric capacitor FC may increase to a value corresponding to the first removing voltage VRV1 along a solid line illustrated in FIG. 10D (i.e., a path corresponding to the time period from t31 to t32).

Afterwards, during the time period from t32 to t33 of FIG. 10A, the third target voltage VTG3 may be applied as the across voltage Vcap. In this case, due to the hysteresis characteristic, the polarization state of the ferroelectric capacitor FC may decrease to a value corresponding to the third target voltage VTG3 along a dash-single dotted line illustrated in FIG. 10D (i.e., a path corresponding to the time period from t32 to t33).

Afterwards, during the time period from t33 to t34 of FIG. 10A, the across voltage Vcap is set to 0 V. In this case, due to the hysteresis characteristic, the polarization state of the ferroelectric capacitor FC may be set to the third polarization state −Pr3 corresponding to the third state ST3 along a dash-double dotted line illustrated in FIG. 10D (i.e., a path corresponding to the time period from t33 to t34).

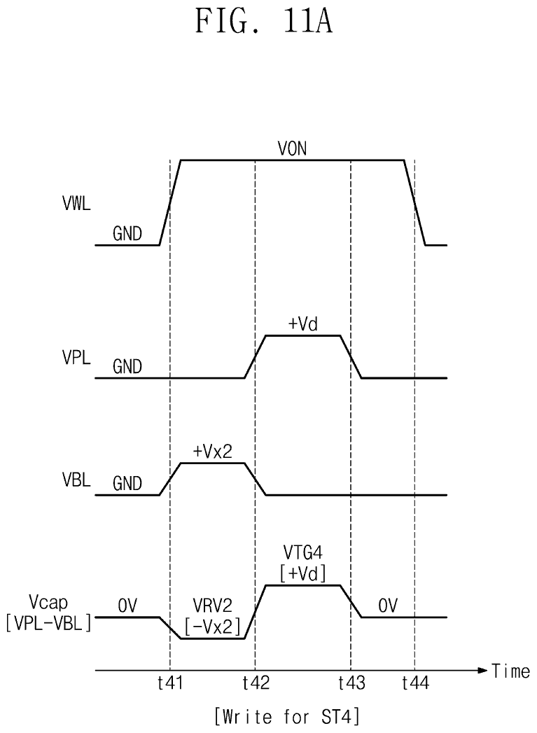

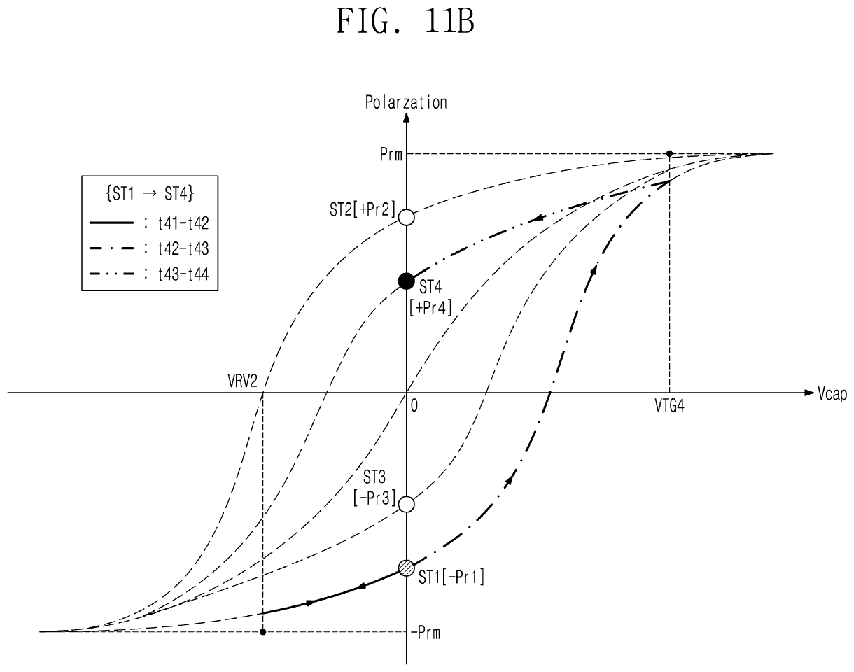

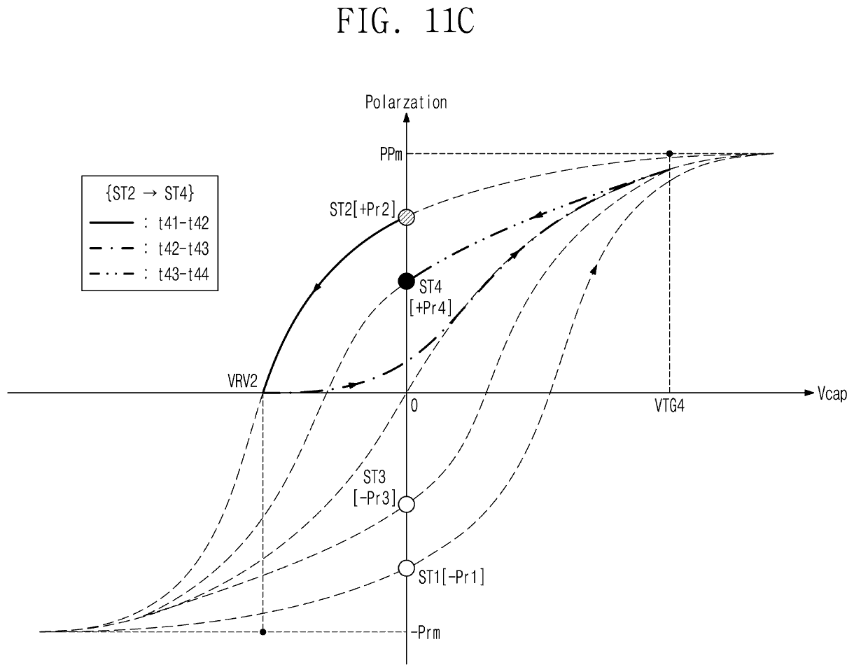

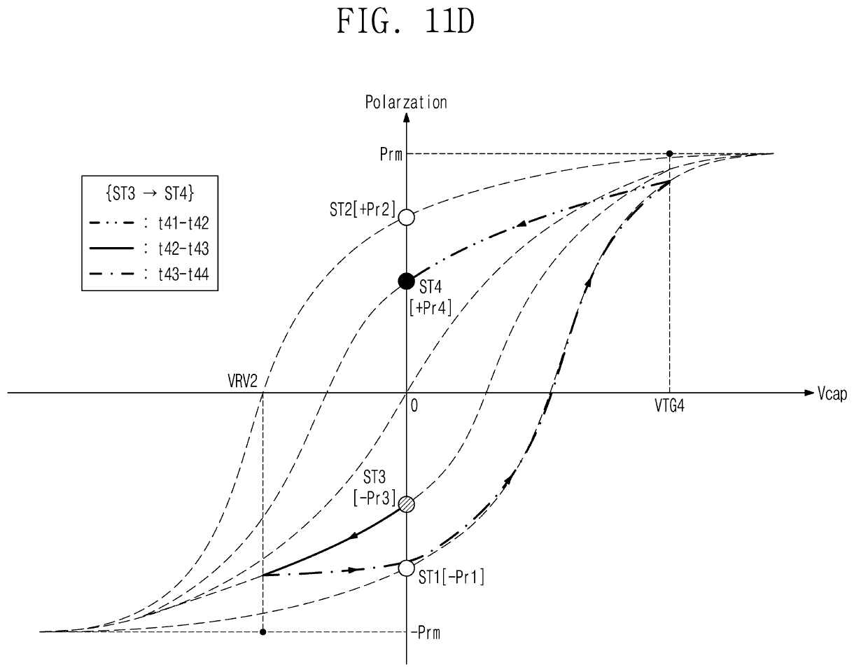

As described above, according to an embodiment of the present disclosure, the write operation on the third state ST3 may be normally performed regardless of the current state of the memory cell MC. Then, the write operation on the fourth state ST4 will be described with reference to FIGS. 11A to 11D. In the timing diagram of FIG. 11A, the horizontal axis represents a time, and the vertical axis represents the word line voltage VWL, the plate line voltage VPL, the bit line voltage VBL, and the across voltage Vcap. In the graphs of FIGS. 11B to 11D, the horizontal axis represents the across voltage Vcap of the ferroelectric capacitor FC, and the vertical axis represents the polarization state of the ferroelectric capacitor FC.

Referring to FIGS. 1, 7, 11A, 11B, 11C, and 11D, the memory device 100 may write the fourth state ST4 in the memory cell MC. For example, during a time period from t41 to t44, the memory device 100 may apply the turn-on voltage VON as the word line voltage VWL. In an embodiment, the turn-on voltage VON may be a high voltage enough to turn on the access transistor TR_ACC of the memory cell MC.

During a time period from t41 to t42, the memory device 100 may maintain the plate line voltage VPL at the ground voltage GND and may apply an x2-th voltage +Vx2 as the bit line voltage VBL. In this case, during the time period from t41 to t42, the across voltage Vcap may be −Vx2. As an example, −Vx2 may correspond to the second removing voltage VRV2. As an example, −Vx2 may be greater than the negative saturation voltage −VCC and may be less than the ground voltage GND. As the across voltage Vcap decreases from 0 V to the second removing voltage VRV2, the polarization state of the ferroelectric capacitor FC may decrease (corresponding to operation S114 of FIG. 7).

Afterwards, during a time period from t42 to t43, the memory device 100 may apply a d-th voltage +Vd as the plate line voltage VPL and may apply the ground voltage GND as the bit line voltage VBL. In this case, during the time period from t42 to t43, the across voltage Vcap may be +Vd. As an example, +Vd may correspond to the fourth target voltage VTG4. As an example, +Vd may be less than the positive saturation voltage +VCC and may be greater than the ground voltage GND. In an embodiment, +Vd may be greater than the first removing voltage VRV1. As the across voltage Vcap increases from the second removing voltage VRV2 to the fourth target voltage VTG4, the polarization state of the ferroelectric capacitor FC may increase (corresponding to operation S124 of FIG. 7).

Next, during a time period from t43 to t44, the memory device 100 may maintain the plate line voltage VPL and the bit line voltage VBL at the ground voltage GND. In this case, during the time period from t43 to t44, the across voltage Vcap may be 0V. As the across voltage Vcap decrease from the fourth target voltage VTG4 to 0 V, the polarization state of the ferroelectric capacitor FC may be stabilized to the fourth polarization state +Pr4 corresponding to the fourth state ST4.

In an embodiment, in each time period described above, the polarization state of the ferroelectric capacitor FC may be variously changed depending on the current state of the memory cell MC or the remanent polarization state of the ferroelectric capacitor FC. However, after the time period from t43 to t44, the polarization state of the ferroelectric capacitor FC may have the fourth polarization state +Pr4 corresponding to the target state (i.e., the fourth state ST4), regardless of the current state of the memory cell MC or the remanent polarization state of the ferroelectric capacitor FC.

As an example, an operation of writing the fourth state ST4 into the memory cell MC when the current state of the memory cell MC is the first state ST1, will be described with reference to FIG. 11B. First, the memory cell MC may have the first state ST1. That is, when the across voltage Vcap is 0 V, the ferroelectric capacitor FC may have the first polarization state −Pr1. During the time period from t41 to t42 of FIG. 11A, the second removing voltage VRV2 may be applied as the across voltage Vcap. In this case, due to the hysteresis characteristic, the polarization state of the ferroelectric capacitor FC may decrease along a solid line illustrated in FIG. 11B (i.e., a path corresponding to the time period from t41 to t42).

Afterwards, during the time period from t42 to t43 of FIG. 11A, the fourth target voltage VTG4 may be applied as the across voltage Vcap. In this case, due to the hysteresis characteristic, the polarization state of the ferroelectric capacitor FC may increase to a value corresponding to the fourth target voltage VTG4 along a dash-single dotted line illustrated in FIG. 11B (i.e., a path corresponding to the time period from t42 to t43). Next, during the time period from t43 to t44 of FIG. 11A, the across voltage Vcap is set to 0 V. In this case, due to the hysteresis characteristic, the polarization state of the ferroelectric capacitor FC may be stabilized to the fourth polarization state +Pr4 corresponding to the fourth state ST4 along a dash-double dotted line of FIG. 11B (i.e., a path corresponding to the time period from t43 to t44).

As another example, an operation of writing the fourth state ST4 into the memory cell MC when the current state of the memory cell MC is the second state ST2, will be described with reference to FIG. 11C. First, the memory cell MC may have the second state ST2. That is, when the across voltage Vcap is 0 V, the ferroelectric capacitor FC may have the second polarization state +Pr2.

During the time period from t41 to t42 of FIG. 11A, the second removing voltage VRV2 may be applied as the across voltage Vcap. In this case, due to the hysteresis characteristic, the polarization state of the ferroelectric capacitor FC may decrease along a solid line illustrated in FIG. 11C (i.e., a path corresponding to the time period from t41 to t42).

Next, during the time period from t42 to t43, the fourth target voltage VTG4 may be applied as the across voltage Vcap. In this case, due to the hysteresis characteristic, the polarization state of the ferroelectric capacitor FC may increase to a value corresponding to the fourth target voltage VTG4 along a dash-single dotted line illustrated in FIG. 11C (i.e., a path corresponding to the time period from t42 to t43).

Then, during the time period from t43 to t44, the across voltage Vcap is maintained at 0 V. In this case, due to the hysteresis characteristic, the polarization state of the ferroelectric capacitor FC may be stabilized to the fourth polarization state +Pr4 corresponding to the fourth state ST4 along a dash-double dotted line illustrated in FIG. 11C (i.e., a path corresponding to the time period from t43 to t44).

Next, during an operation of writing the fourth state ST4 into the memory cell when the current state of the memory cell MC is the third state ST3, will be described with reference to FIG. 11D. First, the memory cell MC may have the third state ST3. That is, when the across voltage Vcap is 0 V, the ferroelectric capacitor FC may have the third polarization state −Pr3. During the time period from t41 to t42 of FIG. 11A, the second removing voltage VRV2 may be applied as the across voltage Vcap. In this case, due to the hysteresis characteristic, the polarization state of the ferroelectric capacitor FC may decrease along a solid line illustrated in FIG. 11D (i.e., a path corresponding to the time period from t41 to t42).

Afterwards, during the time period from t42 to t43, the fourth target voltage VTG4 may be applied as the across voltage Vcap. In this case, due to the hysteresis characteristic, the polarization state of the ferroelectric capacitor FC may increase to a value corresponding to the fourth target voltage VTG4 along a dash-single dotted line illustrated in FIG. 11D (i.e., a path corresponding to the time period from t42 to t43).

Next, during the time period from t43 to t44, the across voltage Vcap is maintained at 0 V. In this case, due to the hysteresis characteristic, the polarization state of the ferroelectric capacitor FC may be stabilized to the fourth polarization state +Pr4 corresponding to the fourth state ST4 along a dash-double dotted line illustrated in FIG. 11D (i.e., a path corresponding to the time period from t43 to t44).

As described above, according to an embodiment of the present disclosure, the memory device 100 may normally write the fourth state ST4 in the memory cell MC regardless of the current state of the memory cell MC, by sequentially applying the second removing voltage VRV2, the fourth target voltage VTG4, and 0 V as the across voltage Vcap of the ferroelectric capacitor FC of the memory cell MC.

As described above, according to an embodiment of the present disclosure, the memory device 100 may perform the 4-level write operation for each memory cell MC regardless of the current state of the memory cell MC, by controlling the across voltage Vcap of the ferroelectric capacitor FC. Advantageously, for the 4-level write operation on the memory cell MC, a separate sensing operation (e.g., an operation of sensing the current state of the memory cell MC) may not be required. Also, the memory device 100 may sequentially apply a removing voltage, a target voltage, and 0 V in association with specific states (e.g., ST3 and ST4). In this manner, a time necessary to set the polarization state of the ferroelectric capacitor FC of the memory cell MC is shortened. This means that the performance of the memory device 100 is typically improved.

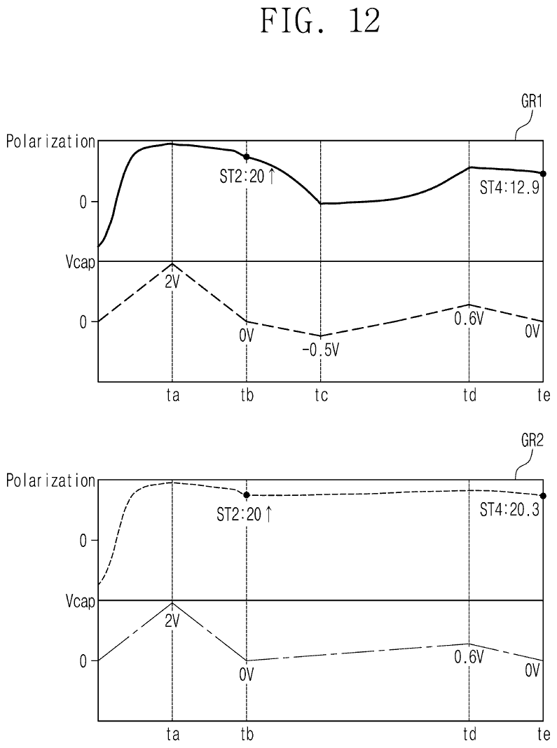

FIG. 12 is a graph illustrating a simulation result of a memory cell according to the timing diagram of FIG. 10A. In first and second graphs GR1 and GR2 of FIG. 12, the horizontal axis represents a time, and the vertical axis represents the polarization state and the across voltage Vcap of the ferroelectric capacitor FC.

An operation in which the fourth state ST4 is written in the memory cell MC having the second state ST2 will be described with reference to FIGS. 1, 2, and 12. According to an embodiment of the present disclosure, the first graph GR1 of FIG. 12 shows a configuration where the second removing voltage VRV2 is applied, and the second graph GR2 of FIG. 12 shows a configuration where the second removing voltage VRV2 is not applied.

As illustrated in the first and second graphs GR1 and GR2 of FIG. 12, at an a-th time point ta, 2 V (e.g., corresponding to the second target voltage VTG2) is applied as the across voltage Vcap. Afterwards, at a b-th time point tb, 0 V is applied as the across voltage Vcap. In this case, the ferroelectric capacitor FC may have the second polarization state +Pr2 (e.g., 20) corresponding to the second state ST2.

Afterwards, as illustrated in the first graph GR1, at a c-th time point tc, the second removing voltage VRV2 (e.g., −0.5 V) may be applied as the across voltage Vcap. In this case, the polarization state of the ferroelectric capacitor FC may be changed to 0 V. Afterwards, as illustrated in the first graph GR1, the fourth target voltage VTG4 (e.g., 0.6 V) may be applied as the across voltage Vcap at a d-th time point td, and 0 V may be applied as the across voltage Vcap at an e-th time point te. Accordingly, the polarization state of the ferroelectric capacitor FC may have the fourth polarization state +Pr4 (e.g., 12.9) corresponding to the fourth state ST4.

In contrast, as illustrated in the second graph GR2, after the b-th time point tb, the fourth target voltage VTG4 (e.g., 0.6 V) may be immediately applied as the d-th time point td. That is, the second removing voltage VRV2 (e.g., −0.5 V) is not applied. In this case, at the e-th time point te, the polarization state of the ferroelectric capacitor FC may be about 20.3 and thus may not be distinguished from the second state ST2. That is, the fourth state ST4 is not normally written in the memory cell MC.

As described above, according to an embodiment of the present disclosure, in the 4-level write operation on the memory cell MC, the removing voltage and the target voltage are sequentially applied as the across voltage Vcap of the ferroelectric capacitor FC. In an embodiment, in the 4-level write operation on the memory cell MC, the removing voltage and the target voltage may be continuously applied as the across voltage Vcap of the ferroelectric capacitor FC. In this case, the normal write operation is possible regardless of the current state of the memory cell MC.

FIG. 13 is a timing diagram for describing an operation of writing a third state in a memory cell, according to an embodiment of FIG. 5. In the timing diagram of FIG. 13, the horizontal axis represents a time, and the vertical axis represents the word line voltage VWL, the plate line voltage VPL, the bit line voltage VBL, and the across voltage Vcap.

In this embodiment, the across voltage Vcap of the ferroelectric capacitor FC corresponds to a difference (e.g., VPL-VBL) between the plate line voltage VPL and the bit line voltage VBL. In this case, in the above embodiments, the across voltage Vcap of the ferroelectric capacitor FC may be controlled by controlling the plate line voltage VPL and the bit line voltage VBL individually. However, the present disclosure is not limited thereto.

For example, as illustrated in FIG. 13, during a time period from t1 to t4, the memory device 100 may apply the turn-on voltage VON as the word line voltage VWL. During the time period from t1 to t4, the memory device 100 may maintain the plate line voltage VPL at the ground voltage GND. During a time period from t1 to t2, the memory device 100 may apply −Vx1 as the bit line voltage VBL. In this case, the across voltage Vcap of the ferroelectric capacitor FC may be the first removing voltage VRV1 (i.e., +Vx1). During a time period from t2 to t3, the memory device 100 may apply +Vc as the bit line voltage VBL. In this case, the across voltage Vcap of the ferroelectric capacitor FC may be the third target voltage VTG3 (i.e., −Vc). During a time period from t3 to t4, the memory device 100 may maintain the bit line voltage VBL at the ground voltage GND. In this case, the across voltage Vcap of the ferroelectric capacitor FC may be 0 V. The change in the polarization state of the ferroelectric capacitor FC according to the across voltage Vcap of each time period is described above, and thus, additional description will be omitted to avoid redundancy.

As described above, according to an embodiment of the present disclosure, the polarization state of the ferroelectric capacitor FC may be controlled by controlling the across voltage Vcap of the ferroelectric capacitor FC. In this case, the across voltage

Vcap may be controlled by controlling the plate line voltage VPL and the bit line voltage VBL individually.

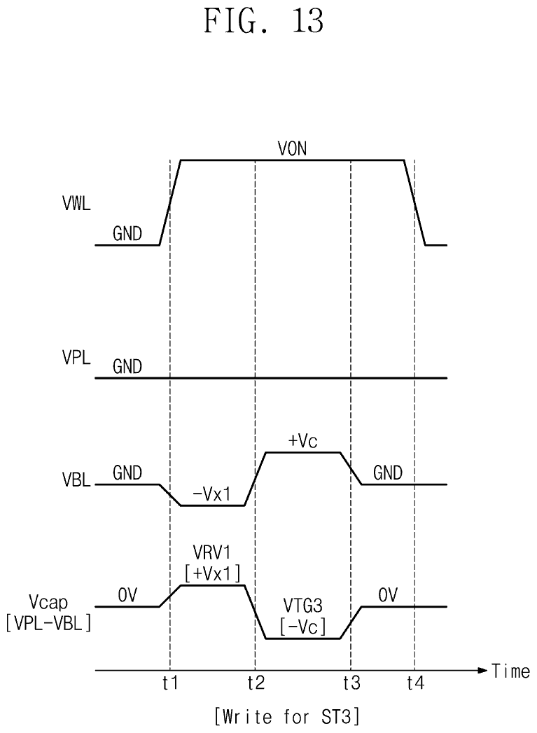

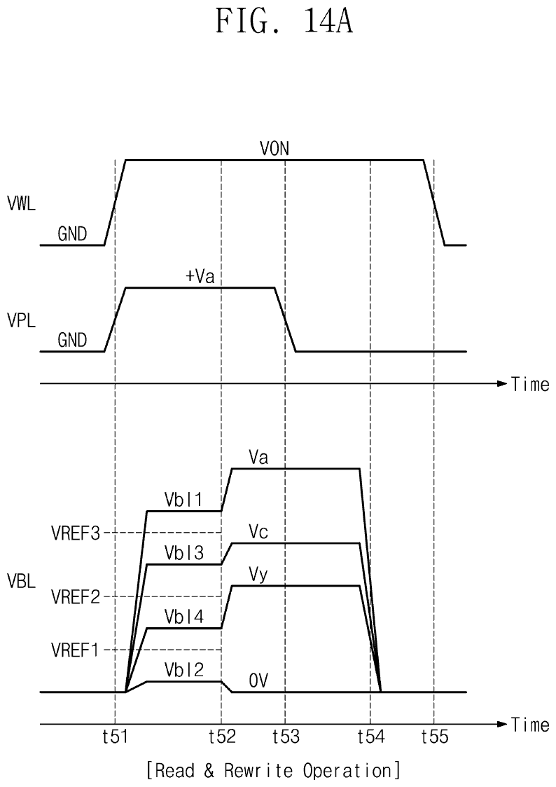

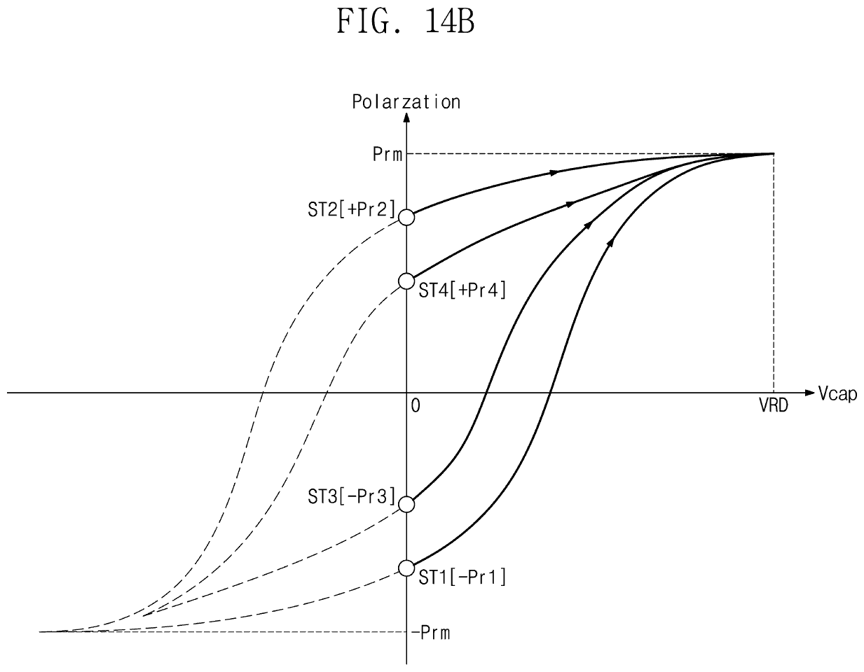

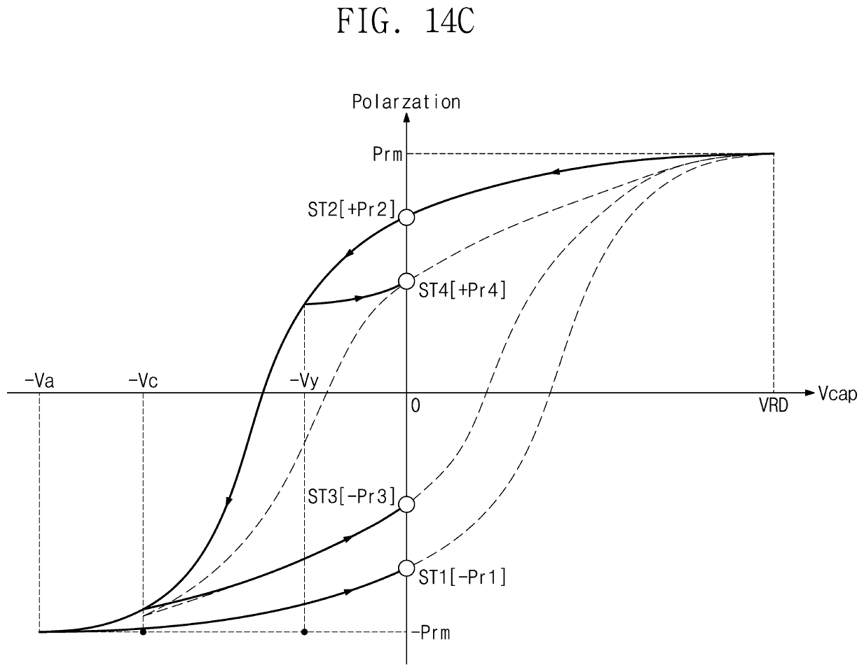

FIGS. 14A to 14C are diagrams for describing a read operation and a rewrite operation on a memory cell experiencing a 4-level write operation according the embodiment of FIG. 5. In the graphs of FIGS. 14B and 14C, the horizontal axis represents the across voltage Vcap of the ferroelectric capacitor FC, and the vertical axis represents the polarization state of the ferroelectric capacitor FC.

For convenience of description, it is assumed that the write operation on the memory cell MC is performed through the operation method described with reference to FIGS. 5 to 13. That is, the memory cell MC may have one of the first to fourth states ST1 to ST4.

First, referring to FIGS. 1, 5, 14A, 14B, and 14C, in a time period from t51 to t55, the memory device 100 may apply the turn-on voltage VON to the word line voltage VWL.

During a time period from t51 to t53, the memory device 100 may apply an a-th voltage +Va as the plate line voltage VPL. In an embodiment, the a-th voltage +Va may correspond to the positive saturation voltage +VCC. In an embodiment, the positive saturation voltage +VCC may indicate the across voltage Vcap by which the polarization state of the ferroelectric capacitor FC is changed to the positive saturation state −Prm. In this case, the across voltage Vcap of the ferroelectric capacitor FC may be +Va, and +Va may correspond to the read voltage VRD. According to the above condition, the polarization state of the ferroelectric capacitor FC may increase to the saturation polarization state +Prm corresponding to the read voltage VRD.

In an embodiment, when the polarization state of the ferroelectric capacitor FC increases to the saturation polarization state +Prm, the variance in the bit line voltage VBL may differ depending on the current polarization state of the ferroelectric capacitor FC. For example, as illustrated in FIG. 14B, when the memory cell MC is in the first state ST1, the ferroelectric capacitor FC has the first polarization state −Pr1. In this case, as the polarization state of the ferroelectric capacitor FC is changed to the saturation polarization state +Prm, as illustrated in FIG. 14A, the bit line voltage VBL may be charged with a first voltage Vbl1.

As illustrated in FIG. 14B, when the memory cell MC is in the second state ST2, the ferroelectric capacitor FC has the second polarization state +Pr2. In this case, as the polarization state of the ferroelectric capacitor FC is changed to the saturation polarization state +Prm, as illustrated in FIG. 14A, the bit line voltage VBL may be charged with a second voltage Vbl2.

As illustrated in FIG. 14B, when the memory cell MC is in the third state ST3, the ferroelectric capacitor FC has the third polarization state −r3. In this case, as the polarization state of the ferroelectric capacitor FC is changed to the saturation polarization state +Prm, as illustrated in FIG. 14A, the bit line voltage VBL may be charged with a third voltage Vbl3. As further illustrated in FIG. 14B, when the memory cell MC is in the fourth state ST4, the ferroelectric capacitor FC has the fourth polarization state +Pr4. In this case, as the polarization state of the ferroelectric capacitor FC is changed to the saturation polarization state +Prm, as illustrated in FIG. 14A, the bit line voltage VBL may be charged with a fourth voltage Vbl4.

In this case, the variance in the polarization state associated with the first state ST1 may be the greatest, the variance in the polarization state associated with the second state ST2 may be the smallest, the variance in the polarization state associated with the third state ST3 may be the second greatest, and the variance in the polarization state associated with the fourth state ST4 may be the second smallest. Accordingly, the magnitudes of the first to fourth voltages Vbl1 to Vbl4 may be in the order of Vbl1>Vbl3 >Vbl4>Vbl2.

The memory device 100 may detect a state of the memory cell MC by sensing a level of the bit line voltage VBL by using first to third reference voltages VREF1 to VREF3. For example, when the bit line voltage VBL is less than the first reference voltage VREF1 (i.e., when the bit line voltage VBL is Vbl2), the memory cell MC is determined as being in the second state ST2. When the bit line voltage VBL is greater than the first reference voltage VREF1 and is less than the second reference voltage VREF2 (i.e., when the bit line voltage VBL is Vbl4), the memory cell MC is determined as being in the fourth state ST4. When the bit line voltage VBL is greater than the second reference voltage VREF2 and is less than the third reference voltage VREF3 (i.e., when the bit line voltage VBL is Vbl3), the memory cell MC is determined as being in the third state ST3. When the bit line voltage VBL is greater than the third reference voltage VREF3 (i.e., when the bit line voltage VBL is Vbl1), the memory cell MC is determined as being in the first state ST1. Through the above operation, the memory device 100 may determine the state of the memory cell MC (i.e., may read data or information stored in the memory cell MC).

In an embodiment, in the read operation described above, the ferroelectric capacitor FC of the memory cell MC may maintain a state having the saturation polarization state +Prm by the read voltage VRD. In this case, as the state of the memory cell MC is changed through the above read operation, the data or information stored in the memory cell MC may be lost. Accordingly, an operation of rewriting the data or information read from the memory cell MC in the memory cell MC may be required.

For example, during the time period from t52 to t53 of FIG. 14A, the memory device 100 may perform an amplification operation on the bit line voltage VBL. As an example, the memory device 100 may set the bit line voltage VBL to the ground voltage GND or 0V, in response to that the bit line voltage VBL is the second voltage Vbl2. As an example, the memory device 100 may amplify the bit line voltage VBL to an y-th voltage Vy, in response to that the bit line voltage VBL is the fourth voltage Vbl4. The memory device 100 may amplify the bit line voltage VBL to the c-th voltage +Vc, in response to that the bit line voltage VBL is the third voltage Vbl3. The memory device 100 may amplify the bit line voltage VBL to the a-th voltage Va, in response to that the bit line voltage VBL is the first voltage Vbl1.

Afterwards, in the time period from t53 to t55, the memory device 100 may maintain the plate line voltage VPL at the ground voltage GND. In the time period from t54 to t55, the bit line voltage VBL may be maintained at the ground voltage GND. In this case, in the time period from t53 to t54, the across voltage Vcap of the ferroelectric capacitor FC may be changed by the bit line voltage VBL.

First, it is assumed that the memory cell MC has the first state ST1 before the read operation. In this case, after the read operation (i.e., after the time period from t51 to t53), the bit line voltage VBL may be charged with the a-th voltage Va; in the time period from t53 to t54, the across voltage Vcap may decrease from the read voltage VRD to −Va. As illustrated in FIG. 14C, as the across voltage Vcap is changed from the read voltage VRD to −Va, the polarization state of the ferroelectric capacitor FC of the memory cell MC may be changed from the saturation polarization state +Prm to the saturation polarization state −Prm. Afterwards, in the time period from t54 to t55, the across voltage Vcap of the ferroelectric capacitor FC may be changed from −Va to 0 V, and thus, the polarization state of the ferroelectric capacitor FC may be stabilized to the first polarization state −Pr1.

It is assumed that the memory cell MC has the second state ST2 before the read operation. In this case, after the read operation (i.e., after the time period from t51 to t53), because the bit line voltage VBL is maintained at the ground voltage GND, in the time period from t53 to t54, the across voltage Vcap may be changed to 0 V. As illustrated in FIG. 14C, as the across voltage Vcap is changed from the read voltage VRD to 0 V, the polarization state of the ferroelectric capacitor FC of the memory cell MC may be changed from the saturation polarization state +Prm to the second polarization state +Pr2.

It is assumed that the memory cell MC has the third state ST3 before the read operation. In this case, because the bit line voltage VBL is charged with the c-th voltage Vc, in the time period from t53 to t54, the across voltage Vcap may be changed from the read voltage VRD to −Vc. Afterwards, in the time period from t54 to t55, the across voltage Vcap may be changed to 0 V. In this case, as illustrated in FIG. 14C, the polarization state of the ferroelectric capacitor FC of the memory cell MC may be changed to the third polarization state −Pr3.

It is assumed that the memory cell MC has the fourth state ST4 before the read operation. In this case, because the bit line voltage VBL is charged with the y-th voltage Vy, in the time period from t53 to t54, the across voltage Vcap may be changed from the read voltage VRD to −Vy. Afterwards, in the time period from t54 to t55, the across voltage Vcap may be changed to 0 V. In this case, as illustrated in FIG. 14C, the polarization state of the ferroelectric capacitor FC of the memory cell MC may be changed to the fourth polarization state +Pr4.

In an embodiment, the a-th, c-th, and y-th voltages Va, Vc, an Vy may be determined in advance depending on the characteristic of the ferroelectric capacitor FC. For example, the a-th voltage Va may correspond to a saturation voltage (e.g., VCC) of the ferroelectric capacitor FC. The c-th voltage Vc may be less than the saturation voltage (e.g., VCC) of the ferroelectric capacitor FC and may be greater than the ground voltage GND. The y-th voltage Vy may be less than the c-th voltage Vc and may be greater than the ground voltage GND. In an embodiment, the y-th voltage Vy may be less than the absolute value of the second removing voltage VRV2.

As described above, the memory device 100 may perform the read operation to determine the state of the memory cell MC. The memory device 100 may perform the rewrite operation such that the determined state is again written in the memory cell MC.

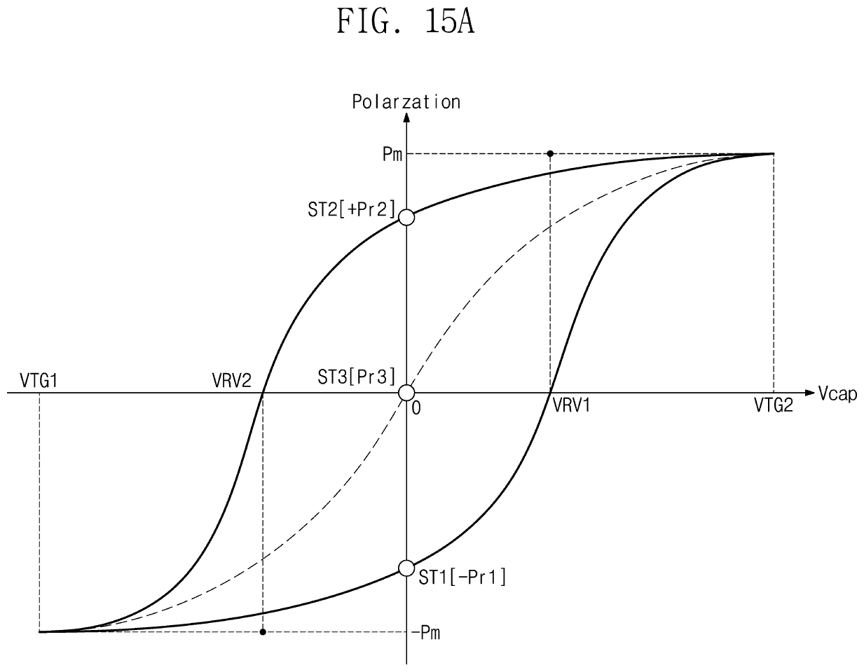

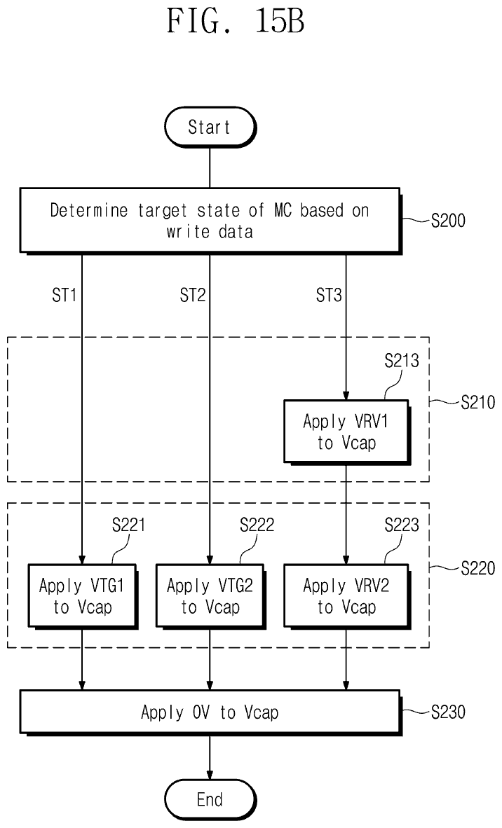

FIGS. 15A and 15B are diagrams for describing a multi-level operation of a memory device of FIG. 1. Referring to FIGS. 1, 2, 15A, and 15B, the memory device 100 may perform the multi-level operation on the memory cell MC. For example, the memory cell MC may have one of first to third states ST1, ST2, and ST3. When the memory cell MC is in the first state ST1, the ferroelectric capacitor FC of the memory cell MC may have the first polarization state −Pr1. When the memory cell MC is in the second state ST2, the ferroelectric capacitor FC of the memory cell MC may have the second polarization state +Pr2. When the memory cell MC is in the third state ST3, the ferroelectric capacitor FC of the memory cell MC may have a third polarization state Pr3. In an embodiment, the third polarization state Pr3 may correspond to “0”.

The memory device 100 may perform the polarization removing operation, the target state setting operation, and the stabilization operation on the memory cell MC to write one of the first to third states ST1, ST2, and ST3 in the memory cell MC.

As an example, in operation S200, the memory device 100 may determine a target state of the memory cell MC based on write data. In operation S210, the memory device 100 may perform the polarization removing operation on the memory cell MC, based on the target state. In operation S220, the memory device 110 may perform the target state setting operation on the memory cell MC based on the target state. For example, when the target state is the first state ST1, in operation S221, the memory device 100 may apply the first target voltage VTG1 as the across voltage Vcap. When the target state is the second state ST2, in operation S222, the memory device 100 may apply the second target voltage VTG2 as the across voltage Vcap. When the target state is the third state ST3, in operation S213, the memory device 100 may apply the first removing voltage VRV1 as the across voltage Vcap in operation S213 and may apply the second removing voltage VRV2 as the across voltage Vcap in operation S223. In an embodiment, the order of applying the first removing voltage VRV1 and the second removing voltage VRV2 may be changed.

Afterwards, in operation S230, the memory device 100 may apply 0 V as the across voltage Vcap. In this case, the ferroelectric capacitor FC of the memory cell MC may have a polarization state corresponding to the target state. The change or setting of the polarization state of the ferroelectric capacitor FC of the memory cell MC is similar to that described above, and thus, additional description will be omitted to avoid redundancy.

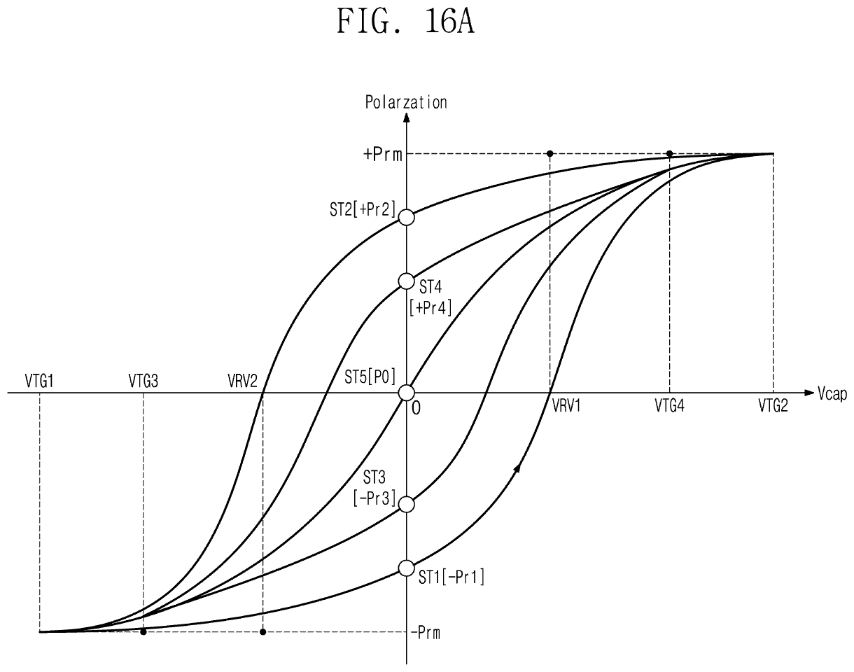

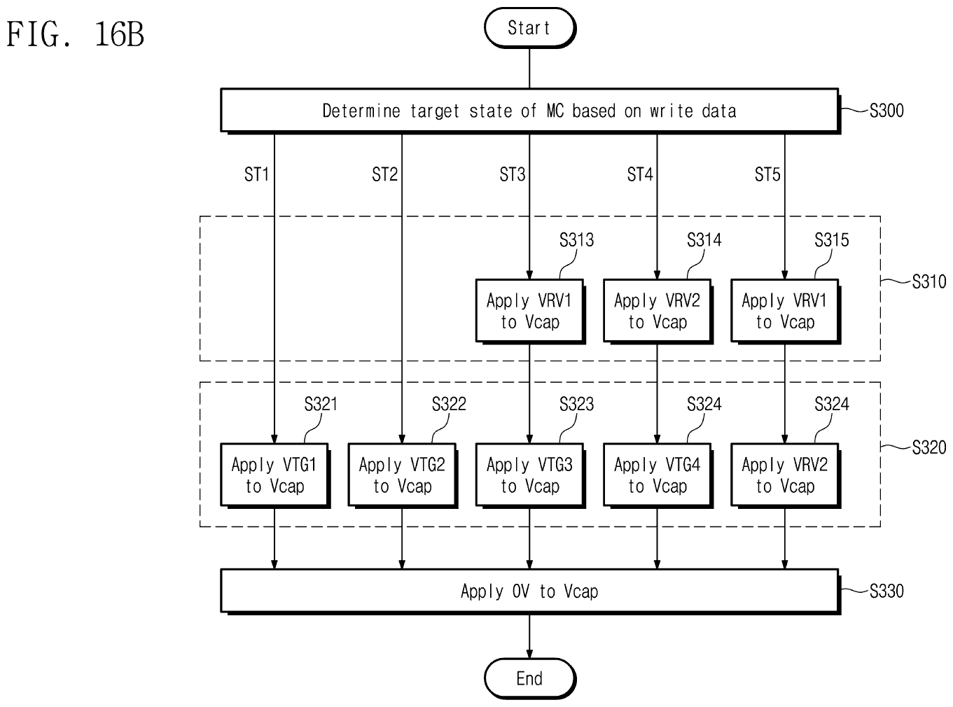

FIGS. 16A and 16B are diagrams for describing a multi-level operation of a memory device of FIG. 1. Referring to FIGS. 1, 2, 16A, and 16B, the memory device 100 may perform the multi-level operation on the memory cell MC. For example, the memory cell MC may have one of first to fifth states ST1, ST2, ST3, ST4, and ST5. When the memory cell MC is in the first state ST1, the ferroelectric capacitor FC of the memory cell MC may have the first polarization state −Pr1. When the memory cell MC is in the second state ST2, the ferroelectric capacitor FC of the memory cell MC may have the second polarization state +Pr2. When the memory cell MC is in the third state ST3, the ferroelectric capacitor FC of the memory cell MC may have the third polarization state −Pr3. When the memory cell MC is in the fourth state ST4, the ferroelectric capacitor FC of the memory cell MC may have the fourth polarization state +Pr4. When the memory cell MC is in the fifth state ST5, the ferroelectric capacitor FC of the memory cell MC may have a fifth polarization state Pr5. In an embodiment, the fifth polarization state Pr5 may correspond to “0”.

The memory device 100 may perform the polarization removing operation, the target state setting operation, and the stabilization operation on the memory cell MC to write one of the first to fifth states ST1, ST2, ST3, ST4, and ST5 in the memory cell MC.

As an example, in operation S300, the memory device 100 may determine a target state of the memory cell MC based on write data. In operation S310, the memory device 100 may perform the polarization removing operation on the memory cell MC, based on the target state. In operation S320, the memory device 110 may perform the target state setting operation on the memory cell MC based on the target state.

For example, when the target state is the first state ST1, in operation S321, the memory device 100 may apply the first target voltage VTG1 as the across voltage Vcap. When the target state is the second state ST2, in operation S322, the memory device 100 may apply the second target voltage VTG2 as the across voltage Vcap. When the target state is the third state ST3, in operation S313, the memory device 100 may apply the first removing voltage VRV1 as the across voltage Vcap. Afterwards, in operation S323, the memory device 100 may apply the third target voltage VTG3 as the across voltage Vcap. When the target state is the fourth state ST4, in operation S314, the memory device 100 may apply the second removing voltage VRV2 as the across voltage Vcap. Afterwards, the memory device 100 may apply the fourth target voltage VTG4 as the across voltage Vcap. When the target state is the fifth state ST5, in operation S315, the memory device 100 may apply the first removing voltage VRV1 as the across voltage Vcap. Afterwards, the memory device 100 may apply the second removing voltage VRV2 as the across voltage Vcap.

Afterwards, in operation S330, the memory device 100 may apply 0 V as the across voltage Vcap. In this case, the ferroelectric capacitor FC of the memory cell MC may have a polarization state corresponding to the target state. The change or setting of the polarization state of the ferroelectric capacitor FC of the memory cell MC is similar to that described above, and thus, additional description will be omitted to avoid redundancy.

As described above, the memory device 100 may include the memory cell MC. The memory cell MC may include the ferroelectric capacitor FC. The memory device 100 may adjust or control the polarization state of the ferroelectric capacitor FC to write multi-level (e.g., 3-level, 4-level, or 5-level) information or data in the memory cell MC. For example, the memory device 100 may write multi-level information in the memory cell MC by performing the polarization removing operation, the target state setting operation, and the stabilization operation on the memory cell MC based on the target state of the memory cell MC.

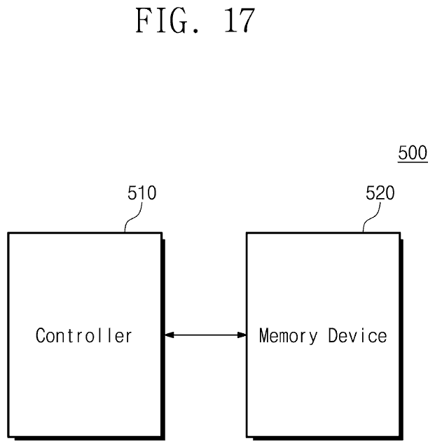

FIG. 17 is a block diagram illustrating a system according to an embodiment of the present disclosure. Referring to FIG. 17, a system 500 may include a controller 510 and a memory device 520. The controller 510 may be configured to control the memory device 520. For example, the controller 510 may transmit a command and an address to the memory device 520. The controller 510 may exchange data with the memory device 520.

In an embodiment, the controller 510 may be a central processing unit (CPU) or an application processor (AP) configured to control all the operations of the system 500 or may be included therein. In an embodiment, the controller 510 may communicate with the memory device 520, based on the DDR interface. However, the present disclosure is not limited thereto. For example, the controller 510 may communicate with the memory device 520 through various interfaces such as an ATA (Advanced Technology Attachment) interface, an SATA (Serial ATA) interface, an e-SATA (external SATA) interface, an SCSI (Small Computer Small Interface) interface, an SAS (Serial Attached SCSI) interface, a PCI (Peripheral Component Interconnection) interface, a PCIe (PCI express) interface, an NVMe (NVM express) interface, an IEEE 1394 interface, an USB (Universal Serial Bus) interface, an SD (Secure Digital) card interface, an MMC (Multi-Media Card) interface, an eMMC (embedded Multi-Media Card) interface, an UFS (Universal Flash Storage) interface, an eUFS (embedded Universal Flash Storage) interface, and a CF (Compact Flash) card interface. In an embodiment, the memory device 520 may be the memory device 100 described with reference to FIGS. 1 to 16B or may operate based on the operation method described with reference to FIGS. 1 to 16B.

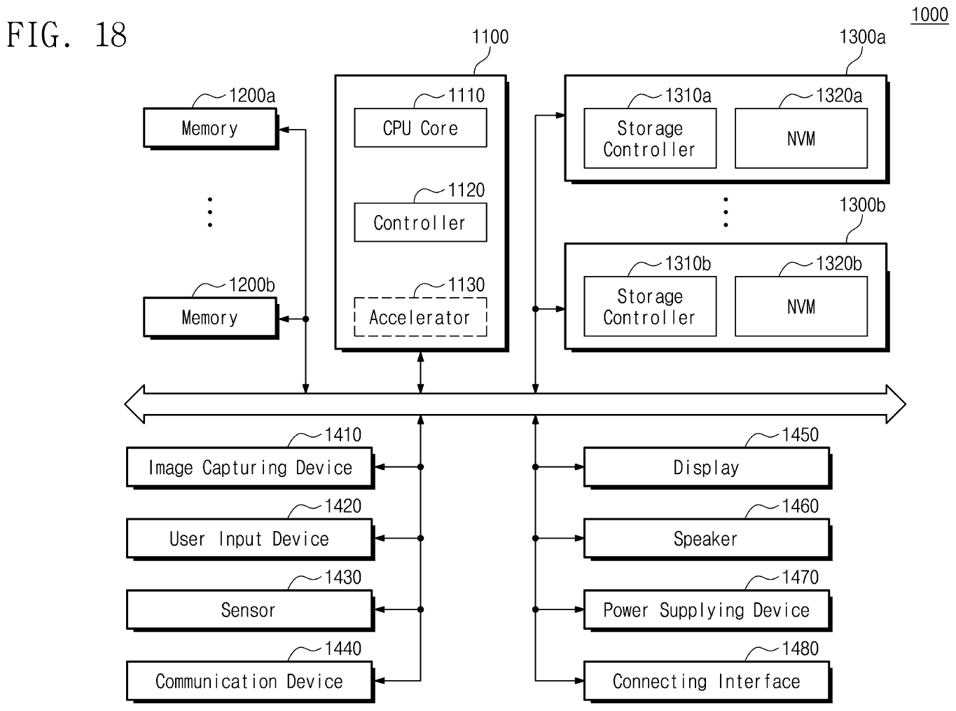

FIG. 18 is a diagram of a system 1000 to which a storage device is applied, according to an embodiment. The system 1000 of FIG. 18 may basically be a mobile system, such as a portable communication terminal (e.g., a mobile phone), a smartphone, a tablet personal computer (PC), a wearable device, a healthcare device, or an Internet of things (IOT) device. However, the system 1000 of FIG. 18 is not necessarily limited to the mobile system and may be a PC, a laptop computer, a server, a media player, or an automotive device (e.g., a navigation device).

Referring to FIG. 18, the system 1000 may include a main processor 1100, memories (e.g., 1200a and 1200b), and storage devices (e.g., 1300a and 1300b). In addition, the system 1000 may include at least one of an image capturing device 1410, a user input device 1420, a sensor 1430, a communication device 1440, a display 1450, a speaker 1460, a power supplying device 1470, and a connecting interface 1480.

The main processor 1100 may control all operations of the system 1000, more specifically, operations of other components included in the system 1000. The main processor 1100 may be implemented as a general-purpose processor, a dedicated processor, or an application processor. The main processor 1100 may include at least one CPU core 1110 and further include a controller 1120 configured to control the memories 1200a and 1200b and/or the storage devices 1300a and 1300b. In some embodiments, the main processor 1100 may further include an accelerator 1130, which is a dedicated circuit for a high-speed data operation, such as an artificial intelligence (Al) data operation. The accelerator 1130 may include a graphics processing unit (GPU), a neural processing unit (NPU) and/or a data processing unit (DPU) and be implemented as a chip that is physically separate from the other components of the main processor 1100.

The memories 1200a and 1200b may be used as main memory devices of the system 1000. Although each of the memories 1200a and 1200b may include a volatile memory, such as static random access memory (SRAM) and/or dynamic RAM (DRAM), each of the memories 1200a and 1200b may include non-volatile memory, such as a flash memory, phase-change RAM (PRAM) and/or resistive RAM (RRAM). The memories 1200a and 1200b may be implemented in the same package as the main processor 1100. The storage devices 1300a and 1300b may serve as non-volatile storage devices configured to store data regardless of whether power is supplied thereto, and have larger storage capacity than the memories 1200a and 1200b. The storage devices 1300a and 1300b may respectively include storage controllers (STRG CTRL) 1310a and 1310b and NVM (Non-Volatile Memory)s 1320a and 1320b configured to store data via the control of the storage controllers 1310a and 1310b. Although the NVMs 1320a and 1320b may include flash memories having a two-dimensional (2D) structure or a three-dimensional (3D) V-NAND structure, the NVMs 1320a and 1320b may include other types of NVMs, such as PRAM and/or RRAM.

The storage devices 1300a and 1300b may be physically separated from the main processor 1100 and included in the system 1000 or implemented in the same package as the main processor 1100. In addition, the storage devices 1300a and 1300b may have types of solid-state devices (SSDs) or memory cards and be removably combined with other components of the system 1000 through an interface, such as the connecting interface 1480 that will be described below. The storage devices 1300a and 1300b may be devices to which a standard protocol, such as a universal flash storage (UFS), an embedded multi-media card (eMMC), or a non-volatile memory express (NVMe), is applied, without being limited thereto.

The image capturing device 1410 may capture still images or moving images. The image capturing device 1410 may include a camera, a camcorder, and/or a webcam. The user input device 1420 may receive various types of data input by a user of the system 1000 and include a touch pad, a keypad, a keyboard, a mouse, and/or a microphone. The sensor 1430 may detect various types of physical quantities, which may be obtained from the outside of the system 1000, and convert the detected physical quantities into electric signals. The sensor 1430 may include a temperature sensor, a pressure sensor, an illuminance sensor, a position sensor, an acceleration sensor, a biosensor, and/or a gyroscope sensor.

The communication device 1440 may transmit and receive signals between other devices outside the system 1000 according to various communication protocols. The communication device 1440 may include an antenna, a transceiver, and/or a modem. The display 1450 and the speaker 1460 may serve as output devices configured to respectively output visual information and auditory information to the user of the system 1000. The power supplying device 1470 may appropriately convert power supplied from a battery (not shown) embedded in the system 1000 and/or an external power source, and supply the converted power to each of components of the system 1000.

The connecting interface 1480 may provide connection between the system 1000 and an external device, which is connected to the system 1000 and capable of transmitting and receiving data to and from the system 1000. The connecting interface 1480 may be implemented by using various interface schemes, such as advanced technology attachment (ATA), serial ATA (SATA), external SATA (e-SATA), small computer small interface (SCSI), serial attached SCSI (SAS), peripheral component interconnection (PCI), PCI express (PCIe), NVMe, IEEE 1394, a universal serial bus (USB) interface, a secure digital (SD) card interface, a multi-media card (MMC) interface, an eMMC interface, a UFS interface, an embedded UFS (eUFS) interface, and a compact flash (CF) card interface.

In an embodiment, the memories 1200a and 1200b may be implemented with the memory device 100 described with reference to FIGS. 1 to 16B. Alternatively, the memories 1200a and 1200b may operate based on the operation method described with reference to FIGS. 1 to 16B.

According to the present disclosure, a memory device may include a plurality of memory cells, each of which includes a ferroelectric capacitor. The memory device may perform a polarization removing operation, a target state setting operation, and a stabilization operation on the memory cells to write multi-level (e.g., 3-level, 4-level, or 5-level) information or data regardless of current states of the memory cells. Accordingly, an operation method of a ferroelectric memory device with reduced costs and improved performance is provided.

While the present disclosure has been described with reference to embodiments thereof, it will be apparent to those of ordinary skill in the art that various changes and modifications may be made thereto without departing from the spirit and scope of the present disclosure as set forth in the following claims.

1. A method of operating a ferroelectric memory cell, comprising:
performing a write operation on the ferroelectric memory cell to program therein a predetermined target state, not corresponding to a saturation polarization state of a ferroelectric capacitor within the ferroelectric memory cell, by:
applying a first removing voltage corresponding to the target state as an across voltage of the ferroelectric capacitor, then
applying a first target voltage corresponding to the target state as the across voltage of the ferroelectric capacitor, and then
applying 0 volts (V), which differs from the first removing voltage and the first target voltage, as the across voltage of the ferroelectric capacitor.

2. The method of claim 1, wherein the target state is preselected from at least three states associated with data to be written into the ferroelectric memory cell;
and wherein, when the target state corresponds to a first polarization state of the ferroelectric capacitor and the first polarization state has a first directivity, the first removing voltage has a first level greater than the 0 V and less than a positive saturation voltage of the ferroelectric capacitor.

3. The method of claim 2, wherein, when the first polarization state of the ferroelectric capacitor corresponding to the target state has the first directivity, the first target voltage has a second level, which is less than 0 V and greater than a negative saturation voltage of the ferroelectric capacitor.

4. The method of claim 3, wherein, when the target state corresponds to a second polarization state of the ferroelectric capacitor and the second polarization state has a second directivity that faces away from the first directivity, the first removing voltage has a third level, which is less than 0 V and greater than the negative saturation voltage of the ferroelectric capacitor.

5. The method of claim 4, wherein, when the target state corresponds to the second polarization state of the ferroelectric capacitor and the second polarization state has a second directivity facing away from the first directivity, the first target voltage has a fourth level, which is greater than 0 V and less than the positive saturation voltage of the ferroelectric capacitor.

6. The method of claim 5, wherein an absolute value of the fourth level is greater than an absolute value of the first level, and an absolute value of the second level is greater than an absolute value of the third level.

7. The method of claim 1, wherein, when the target state corresponds to the saturation polarization state of the ferroelectric capacitor, the write operation includes:
applying a second target voltage corresponding to the target state as the across voltage of the ferroelectric capacitor; and then
applying 0 V as the across voltage of the ferroelectric capacitor.

8. The method of claim 7, wherein, when the saturation polarization state of the ferroelectric capacitor corresponding to the target state has a first directivity, the second target voltage is equal to a positive saturation voltage of the ferroelectric capacitor.

9. The method of claim 8, wherein, when the saturation polarization state of the ferroelectric capacitor corresponding to the target state has a second directivity that faces away from the first directivity, the second target voltage is equal to a negative saturation voltage of the ferroelectric capacitor.

10. The method of claim 1, wherein the across voltage of the ferroelectric capacitor is applied to a plate line and a bit line, which are electrically connected to the ferroelectric memory cell.

11. The method of claim 10, further comprising:
applying a read voltage to the plate line;
determining the target state of the ferroelectric memory cell by sensing a voltage of the bit line based on a plurality of reference voltages;
amplifying a voltage of the bit line; and
applying a ground voltage to the plate line.

12. The method of claim 11, wherein the read voltage is a positive saturation voltage of the ferroelectric capacitor.

13. The method of claim 11,
wherein, when the voltage of the bit line is greater than a first reference voltage among the plurality of reference voltages and is less than a second reference voltage among the plurality of reference voltages, the voltage of the bit line is amplified to a first voltage; and
wherein, when the voltage of the bit line is greater than the second reference voltage among the plurality of reference voltages and is less than a third reference voltage among the plurality of reference voltages, the voltage of the bit line is amplified to a second voltage greater than the first voltage.

14. The method of claim 13, wherein the first voltage is less than an absolute value of the first removing voltage.

15. The method of claim 13,
wherein, when the voltage of the bit line is less than the first reference voltage, the voltage of the bit line is amplified to the ground voltage; and
wherein, when the voltage of the bit line is greater than the third reference voltage, the voltage of the bit line is amplified to the positive saturation voltage of the ferroelectric capacitor.

16. A method of operating a memory device having a ferroelectric memory cell therein, the method comprising:
determining a target state among at least three states based on data to be written into the ferroelectric memory cell; then
when the target state is a first target state, applying a first target voltage as an across voltage of a ferroelectric capacitor of the ferroelectric memory cell;
when the target state is a second target state, applying a second target voltage as the across voltage of the ferroelectric capacitor;
when the target state is a third target state, continuously applying a first removing voltage and a third target voltage as the across voltage of the ferroelectric capacitor;
when the target state is a fourth target state, continuously applying a second removing voltage and a fourth target voltage as the across voltage of the ferroelectric capacitor; and
applying 0 V as the across voltage of the ferroelectric capacitor.

17. The method of claim 16,
wherein each of the first target voltage, the third target voltage, and the second removing voltage is a negative voltage;
wherein each of the second target voltage, the fourth target voltage, and the first removing voltage is a positive voltage;
wherein an absolute value of the first target voltage is greater than an absolute value of the third target voltage;
wherein the absolute value of the third target voltage is greater than an absolute value of the second removing voltage;
wherein an absolute value of the second target voltage is greater than an absolute value of the fourth target voltage; and
wherein the absolute value of the fourth target voltage is greater than an absolute value of the first removing voltage.

18. A method of operating a memory device having a ferroelectric memory cell therein that supports at least three nonvolatile memory states, comprising:
performing a polarization removing operation on the ferroelectric memory cell;
performing a target state setting operation on the ferroelectric memory cell; and
performing a stabilization operation on the ferroelectric memory cell.

19. The method of claim 18, wherein the polarization removing operation is performed by applying a removing voltage as an across voltage of a ferroelectric capacitor of the ferroelectric memory cell; and wherein the target state setting operation is performed by applying a target voltage as the across voltage of the ferroelectric capacitor.

20. The method of claim 19,
wherein, when the removing voltage is a negative voltage, the target voltage is a positive voltage;
wherein, when the removing voltage is a positive voltage, the target voltage is a negative voltage; and
wherein an absolute value of the removing voltage is less than an absolute value of the target voltage.

21.-25. (canceled)
